(19) United States
(12) Patent Application Publication
(10) Pub. No.: US 2026/0202495 A1
(43) Pub. Date: Jul. 16, 2026

(54) METHOD AND SYSTEM FOR IMPROVING DYNAMIC RANGE OF MAGNETIC RESONANCE RADIO FREQUENCY EMISSION SIGNAL AND SYSTEM

(71) Applicant: SHANGHAI UNITED IMAGING HEALTHCARE CO., LTD., Shanghai (CN)

(72) Inventors: Zhekang YAN, Shanghai (CN); Xiaolei GUAN, Shanghai (CN)

(73) Assignee: SHANGHAI UNITED IMAGING HEALTHCARE CO., LTD., Shanghai (CN)

(21) Appl. No.: 19/562,724

(22) Filed: Mar. 10, 2026

Related U.S. Application Data
(63) Continuation of application No. PCT/CN2024/130990, filed on Nov. 8, 2024.

(30) Foreign Application Priority Data
Nov. 10, 2023 (CN) 202311501097.X

(51) Int. Cl. G01R 33/36

(52) U.S. Cl. CPC G01R 33/3607

(57) ABSTRACT

The embodiments of the present disclosure provide a device for improving a dynamic range of a magnetic resonance RF emission signal. The device comprises an instruction processing module, configured to receive a magnetic resonance sequence instruction, and output a baseband signal and a frequency tuning word corresponding to a preset frequency; a coefficient generation module, configured to output a noise filter coefficient based on the frequency tuning word; and a pulse generation module, configured to output a target radio frequency signal based on the baseband signal, the frequency tuning word, and the noise filter coefficient.

### CROSS-REFERENCE TO RELATED APPLICATION

This application is a Continuation of International Application No. PCT/CN2024/130990 filed on Nov. 8, 2024, which claims priority to Chinese Application No. 202311501097.X, filed on Nov. 10, 2023, the entire contents of which are incorporated herein by reference.

### TECHNICAL FIELD

The present disclosure relates to the field of medical equipment technology, and in particular to a device, a method and a system for improving a dynamic range of a magnetic resonance radio frequency (RF) emission signal.

### BACKGROUND

Magnetic resonance imaging (MRI) is widely used in clinical medical examination and scientific experimental research. With the continuous development of the field of magnetic resonance technology research, the technology of multi-nuclide and multi-channel parallel excitation and acquisition has emerged to provide more comprehensive detection functions, realizing more access to metabolic information of patients. At present, multi-nuclide and multi-channel MRI equipment usually needs to be equipped with a plurality of digital-to-analog converters and emission coils for imaging RF signals of different types of nuclides. However, due to the differences in the resonance frequencies and/or emission powers of different nuclides, and the nonlinear characteristics of existing digital-to-analog conversion chips in the small signal region, the requirements for the overall dynamic range of the equipment are difficult to achieve.

Therefore, it is desirable to provide a device and a method for improving the dynamic range of a magnetic resonance RF emission signal and a system.

### SUMMARY

The embodiments of the present disclosure provide a device for improving a dynamic range of a magnetic resonance radio frequency (RF) emission signal. The device may comprise an instruction processing module, configured to receive a magnetic resonance sequence instruction and output a baseband signal and a frequency tuning word corresponding to a preset frequency; a coefficient generation module, configured to output, based on the frequency tuning word, a noise filter coefficient; and a pulse generation module, configured to output a target RF signal based on the baseband signal, the frequency tuning word, and the noise filter coefficient.

In some embodiments, the preset frequency may correspond to a resonance frequency of an excited nuclide.

In some embodiments, the instruction processing module may be configured to output, based on the magnetic resonance sequence instruction, two or more baseband signals and frequency tuning words corresponding to two or more preset frequencies.

In some embodiments, the pulse generation module may include at least one noise shaping unit configured to perform, based on the noise filter coefficient, noise shaping on an initial RF signal or an intermediate RF signal to output the target RF signal. The initial RF signal may be generated based on the baseband signal and the frequency tuning word.

In some embodiments, a count of bits of the target RF signal may be less than a count of bits of the initial RF signal, and the count of bits of the target RF signal may be less than a count of bits of the intermediate RF signal.

In some embodiments, the noise shaping unit may be further configured to: perform, based on the noise filter coefficient, noise shaping on the initial RF signal or the intermediate RF signal through a noise shaping filter.

In some embodiments, one or more parameters of the noise shaping filter may correspond to the resonance frequency of the excited nuclide.

In some embodiments, the pulse generation module may include two or more noise shaping units. The one or more parameters of at least one of two or more noise shaping filters corresponding to the two or more noise shaping units may be different from parameters of other noise shaping filters.

In some embodiments, the noise shaping may include: obtaining a signal to be optimized; obtaining, based on the signal to be optimized, a disturbance signal, the disturbance signal being a preset count of low bits in the signal to be optimized; inputting the disturbance signal into the noise shaping filter, the noise shaping filter outputting a disturbance optimization signal; obtaining, based on the initial RF signal or the intermediate RF signal, and the disturbance optimization signal, an optimized signal; and obtaining, based on the optimized signal, the target RF signal.

In some embodiments, the pulse generation module may include at least one pulse generation channel, each of the at least one pulse generation channel corresponds to one noise shaping unit. The one noise shaping unit may be configured to receive the noise filter coefficient corresponding to the at least one pulse generation channel, and perform, based on the noise filter coefficient, noise shaping on the initial RF signal or the intermediate RF signal corresponding to the pulse generation channel.

In some embodiments, the pulse generation module may further include at least one digital-to-analog conversion unit corresponding to the at least one pulse generation channel. The at least one digital-to-analog conversion unit may be configured to perform digital-to-analog conversion on the target RF signal of the at least one pulse generation channel corresponding to the least one digital-to-analog conversion unit.

In some embodiments, the pulse generation module may further include: at least one merging unit corresponding to two or more of the at least one pulse generation channel and configured to merge the target RF signals output by the two or more of the at least one pulse generation channel to output a merged target RF signal; and at least one digital-to-analog conversion unit connected with the at least one merging unit and configured to perform digital-to-analog conversion on the merged target RF signal.

In some embodiments, the pulse generation module may include multiple pulse generation channels and at least one merging unit. The at least one merging unit may correspond to two or more of the multiple pulse generation channels and configured to merge the initial RF signals output by the two or more of the at least one pulse generation channels to output an intermediate RF signal; and the at least one noise shaping unit may be connected with the at least one merging unit and configured to receive the noise filter coefficient corresponding to the at least one pulse generation channel, and perform, based on the noise filter coefficient, noise shaping on the intermediate RF signal output by the at least one merging unit to output the target RF signal.

In some embodiments, the pulse generation module may further include: at least one digital-to-analog conversion unit connected with the noise shaping unit and configured to perform digital-to-analog conversion on the target RF signal.

In some embodiments, the pulse generation channel may include a frequency mixing link. The frequency mixing link may be configured to receive the baseband signal and the frequency tuning word corresponding to the at least one pulse generation channel, and generate, based on the baseband signal and the frequency tuning word, the initial RF signal.

In some embodiments, frequency mixing link may include a numerically controlled oscillator configured to generate, based on the frequency tuning word, a local oscillation signal; and an up-conversion modulator connected with the numerically controlled oscillator and configured to generate, based on the local oscillator signal and the baseband signal, the initial RF signal.

In some embodiments, the pulse generation module may further include a switch connected with the noise shaping unit and configured to build or block a connection between the noise shaping unit and the at least one pulse generation channel.

In some embodiments, the coefficient generation module may be further configured to: determine, based on the frequency tuning word and one or more system configuration parameters of a magnetic resonance device, the noise filter coefficient.

In some embodiments, the coefficient generation module may be further configured to: determine, based on the frequency tuning word and/or the one or more system configuration parameters of the magnetic resonance device, the noise filter coefficient through a frequency index coefficient table.

In some embodiments, the coefficient generation module may be further configured to: determine, based on the frequency tuning word and/or the one or more system configuration parameters of the magnetic resonance device, the noise filter coefficient through a preset algorithm.

In some embodiments, the instruction processing module may be further configured to: determine, based on a center frequency of an emission signal, a corresponding frequency tuning word.

In some embodiments, the device may further comprise: an emission link, configured to perform signal conditioning and power amplification on the target RF signal; and an emission coil connected with the emission link and configured to transmit, based on a signal output by the emission link, an imaging RF signal.

The embodiments of the present disclosure further provide a method for improving a dynamic range of a magnetic resonance radio frequency (RF) emission signal. The method may comprise: inputting a magnetic resonance sequence instruction, and outputting a baseband signal and a frequency tuning word corresponding to a preset frequency; outputting, based on the frequency tuning word, a noise filter coefficient; and outputting a target RF signal based on the baseband signal, the frequency tuning word, and the noise filter coefficient.

The embodiments of the present disclosure further provide a magnetic resonance imaging (MRI) system, comprising an imaging device and a radio frequency (RF) emission unit. The RF emission unit may be connected with the imaging device. The RF emission unit may include a host computer and the device described in any embodiment of the present disclosure. The host computer may be configured to send a magnetic resonance sequence instruction. The device may be configured to receive the magnetic resonance sequence instruction and emit an imaging RF signal corresponding to a magnetic resonance sequence.

### BRIEF DESCRIPTION OF THE DRAWINGS

The present disclosure will be further illustrated by way of exemplary embodiments, which will be described in detail by means of the accompanying drawings. These embodiments are not limiting, and in these embodiments, the same numbering indicates the same structure, wherein:

FIG. 1 is a block diagram illustrating an exemplary device for improving a dynamic range of a magnetic resonance radio frequency (RF) emission signal according to some embodiments of the present disclosure;

FIG. 2 is a schematic diagram illustrating an electrical principal of an exemplary device for improving a dynamic range of a magnetic resonance radio frequency (RF) emission signal according to some embodiments of the present disclosure;

FIG. 3 is a block diagram illustrating an exemplary pulse generation module according to some embodiments of the present disclosure;

FIG. 4A is a block diagram illustrating an exemplary pulse generation module according to some embodiments of the present disclosure;

FIG. 4B is a block diagram illustrating an exemplary pulse generation module according to some embodiments of the present disclosure;

FIG. 4C is a block diagram illustrating an exemplary pulse generation module according to some embodiments of the present disclosure;

FIG. 4D is a block diagram illustrating an exemplary pulse generation module according to some embodiments of the present disclosure;

FIG. 5A is a block diagram illustrating an exemplary frequency mixing link according to some embodiments of the present disclosure;

FIG. 5B is a block diagram illustrating an exemplary frequency mixing link according to some embodiments of the present disclosure;

FIG. 6 is schematic diagram illustrating an electrical principal of an exemplary pulse generation module according to some embodiments of the present disclosure;

FIG. 7 is a logic block diagram illustrating an exemplary hardware or software of a noise shaping unit according to some embodiments of the present disclosure;

FIG. 8 is a flowchart illustrating an exemplary method for improving a dynamic range of a magnetic resonance radio frequency (RF) emission signal according to some embodiments of the present disclosure;

FIG. 9 is a schematic diagram illustrating an exemplary time domain response of an analog simulation signal according to some embodiments of the present disclosure;

FIG. 10 is a schematic diagram illustrating an exemplary frequency domain response of an analog simulation signal according to some embodiments of the present disclosure;

FIG. 11 is a schematic diagram illustrating an exemplary frequency domain response of a digital simulation signal according to some embodiments of the present disclosure;

FIG. 12 is a schematic diagram illustrating partial enlargement of an exemplary frequency domain response of a digital simulation signal according to some embodiments of the present disclosure;

FIG. 13 is a schematic diagram illustrating an exemplary frequency domain response of a truncated signal of a digital simulation signal according to some embodiments of the present disclosure;

FIG. 14 is a schematic diagram illustrating partial enlargement of an exemplary frequency domain response of a truncated signal of a digital simulation signal according to some embodiments of the present disclosure;

FIG. 15 is a schematic diagram illustrating an exemplary frequency domain response of a truncated signal output after noise shaping is performed on a digital simulation signal according to some embodiments of the present disclosure; and

FIG. 16 is a schematic diagram illustrating partial enlargement of an exemplary frequency domain response of a truncated signal output after noise shaping is performed on a digital simulation signal according to some embodiments of the present disclosure.

### DETAILED DESCRIPTION

In order to more clearly illustrate the technical solutions of the embodiments of the present disclosure, the accompanying drawings required to be used in the description of the embodiments are briefly described below. Obviously, the accompanying drawings in the following description are only some examples or embodiments of the present disclosure, and it is possible for a person of ordinary skill in the art to apply the present disclosure to other similar scenarios in accordance with these drawings without creative labor. Unless obviously obtained from the context or the context illustrates otherwise, the same numeral in the drawings refers to the same structure or operation.

It should be understood that the terms “system”, “device”, “unit” and/or “module” used herein are a way to distinguish between different components, elements, parts, sections, or assemblies at different levels. However, the terms may be replaced by other expressions if other words accomplish the same purpose.

As shown in the present disclosure and in the claims, unless the context clearly suggests an exception, the words “one”, “a”, “an”, “one kind”, and/or “the” do not refer specifically to the singular, but may also include the plural. Generally, the terms “including” and “comprising” suggest only the inclusion of clearly identified steps and elements, however, the steps and elements that do not constitute an exclusive list, and the method or apparatus may also include other steps or elements.

Flowcharts are used in the present disclosure to illustrate the operations performed by a system according to embodiments of the present disclosure, and the related descriptions are provided to aid in a better understanding of the magnetic resonance imaging method and/or system. It should be appreciated that the preceding or following operations are not necessarily performed in an exact sequence. Instead, steps can be processed in reverse order or simultaneously. Also, it is possible to add other operations to these processes or to remove a step or steps from these processes.

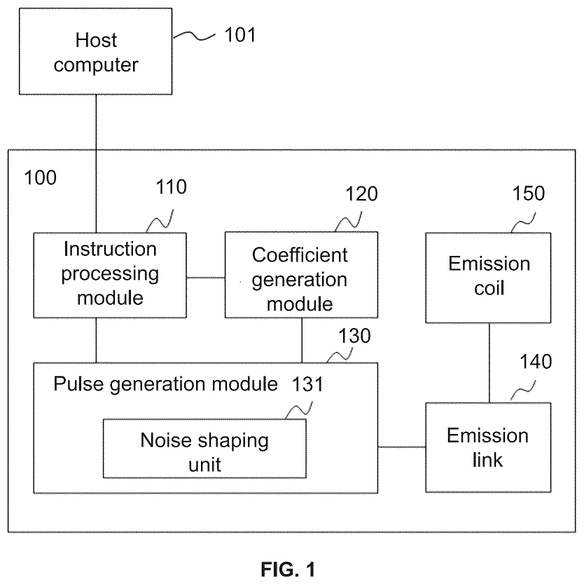

FIG. 1 is a block diagram illustrating an exemplary device for improving the dynamic range of a magnetic resonance radio frequency (RF) emission signal according to some embodiments of the present disclosure.

In some embodiments, a device 100 for improving the dynamic range of a magnetic resonance RF emission signal (hereinafter referred to as the device 100) may include an instruction processing module 110, a coefficient generation module 120, and a pulse generation module 130. In some embodiments, all or part of the instruction processing module 110, the coefficient generation module 120, and the pulse generation module 130 may be implemented on the device 100 through hardware, software programs, firmware, or a combination thereof.

In some embodiments, the instruction processing module 110 may be configured to receive a magnetic resonance sequence instruction and output a baseband signal and a frequency tuning word (FTW) corresponding to a preset frequency.

The instruction processing module 110 refers to a module for processing the magnetic resonance sequence instruction, and is configured to convert an instruction input by a user (e.g., a doctor, a nurse for operating a magnetic resonance device) into a form that can be recognized and executed by the magnetic resonance device through a host computer (e.g., host computer 101) to perform emission of the magnetic resonance RF emission signal and subsequent imaging. In some embodiments, the instruction processing module may be configured to receive the magnetic resonance sequence instructions sent by the host computer, perform instruction analysis according to a preset instruction format, an instruction parsing protocol, etc., and output the baseband signal and the frequency tuning word corresponding to the preset frequency.

The magnetic resonance sequence instruction may be used to control the magnetic resonance device to emit signals according to a specified parameter. In some embodiments, the magnetic resonance sequence instruction may include one or more parameters related to the emission signal. For example, the one or more parameters may include at least one of a nuclide type, a count of nuclides, a frequency tuning parameter (e.g., including the preset frequency), a baseband signal parameter (e.g., including a pulse duration, an amplitude, etc.), a pulse sequence parameter, emission power, channel information, etc.

In some embodiments, the magnetic resonance sequence instruction may include one or more frequency tuning parameters and one or more baseband signal parameters corresponding to one or more preset frequencies. The instruction processing module 110 may perform instruction analysis on the input magnetic resonance sequence instruction and output two or more baseband signals and two or more frequency tuning words corresponding to the two or more preset frequencies.

Merely by way of example, the magnetic resonance sequence instruction may include a plurality of frequency tuning parameters and a plurality of baseband signal parameters corresponding to a plurality of preset frequencies. The instruction processing module 110 may perform instruction analysis on the input magnetic resonance sequence instruction and output the plurality of baseband signals and the plurality of frequency tuning words corresponding to the plurality of preset frequencies.

The preset frequency refers to a frequency at which the magnetic resonance device is expected to emit the signal. The preset frequency may be a resonance frequency corresponding to a nuclide.

In some embodiments, one or more preset frequencies may be provided. That is, the magnetic resonance device may perform single-nuclide imaging or multi-nuclide imaging. In some embodiments, the preset frequency may correspond to a resonance frequency of an excited nuclide.

The nuclide may include 1H, Na, P, 31P, 13C, 19F, 3He, 129Xe, or the like. In some embodiments, one preset frequency may be provided, i.e., the magnetic resonance device may perform single-nuclide imaging. For example, if MRI is performed using the 1H nuclide, and the resonance frequency of the 1H nuclide is 42.577 MHz, the preset frequency may be the resonance frequency (i.e., 42.577 MHz) of the 1H nuclide. In this case, the instruction processing module 110 may output a baseband signal and a frequency tuning word corresponding to the resonance frequency (i.e., 42.577 MHz) of the 1H nuclide.

In some embodiments, two preset frequencies may be provided, i.e., the magnetic resonance device may perform two-nuclide imaging. For example, if MRI is performed using the 1H nuclide and the Na nuclide, the preset frequency may include a resonance frequency of the 1H nuclide and a resonance frequency of the Na nuclide. In this case, the instruction processing module 110 may output two baseband signals and two frequency tuning words. One of the two baseband signals and one of the two frequency tuning words may correspond to the resonance frequency (i.e., 42.577 MHz) of the 1H nuclide, and the other of the two baseband signals and the other of the two frequency tuning words may correspond to the resonance frequency of the Na nuclide.

In some embodiments, more than two preset frequencies may be provided, i.e., the magnetic resonance device may perform imaging using more than two nuclides. For example, if MRI is performed using the 1H nuclide, the Na nuclide, and the 19F nuclide, the preset frequency may include the resonance frequency of the 1H nuclide, the resonance frequency of the Na nuclide, and a resonance frequency of the 19F nuclide. In this case, the instruction processing module 110 may output three baseband signals and three frequency tuning words. The first of the three baseband signals and the first of the three frequency tuning words may correspond to the resonance frequency of the 1H nuclide, the second of the three baseband signals and the second of the three frequency tuning words may correspond to the resonance frequency of the Na nuclide, and the third of the three baseband signals and the third of the three frequency tuning words may correspond to the resonance frequency of the 19F nuclide.

Compared with single 1H nuclide, multiple nuclides have a larger chemical shift range, and the results obtained from MRI using multiple nuclides can provide more comprehensive functional and metabolic information.

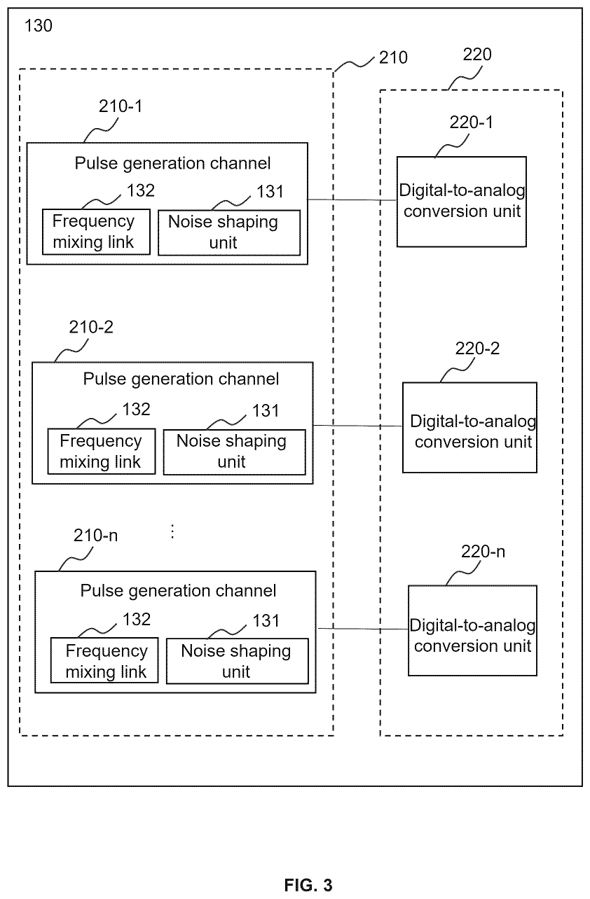

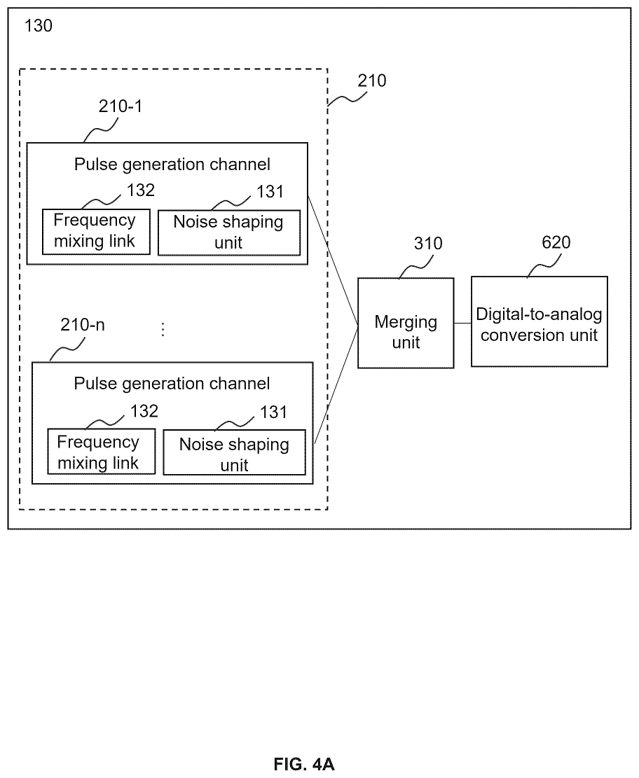

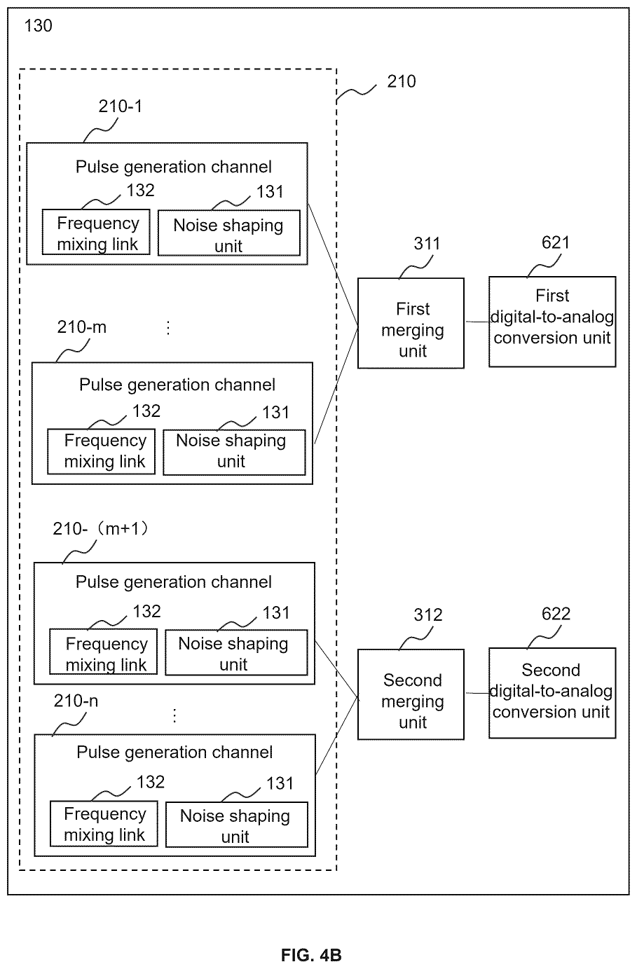

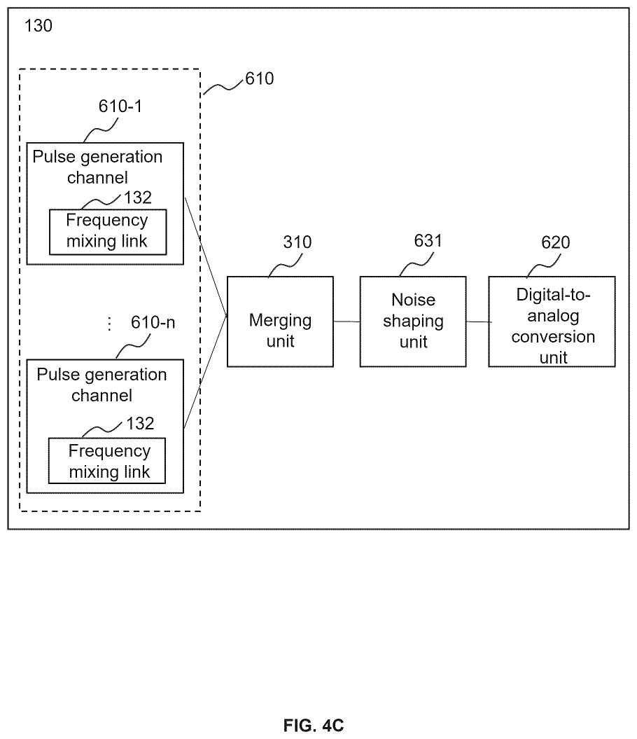

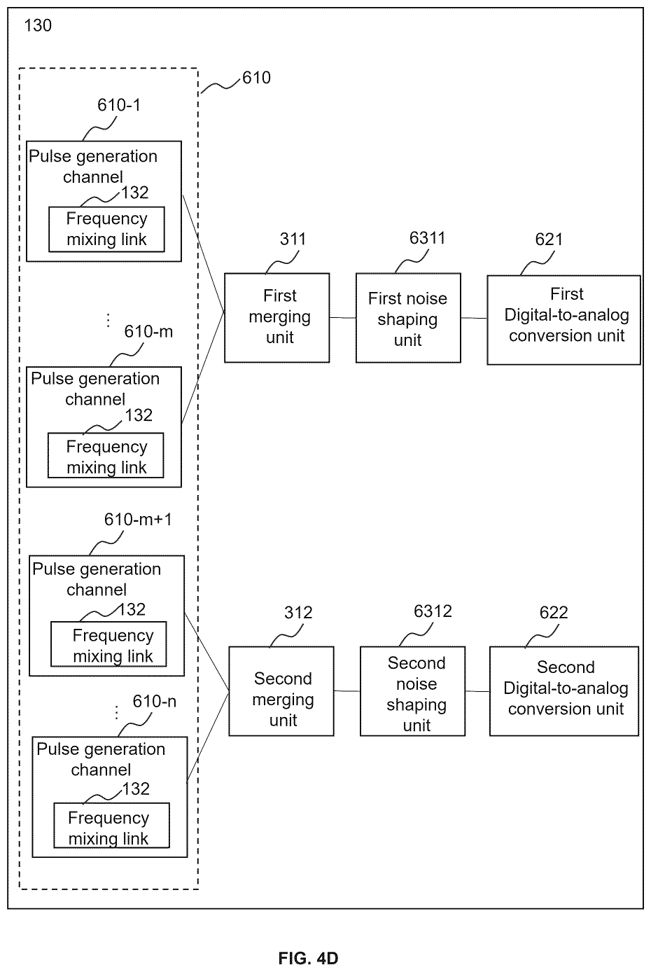

If a plurality of preset frequencies are provided, the implementation manner of the device 100 may be found in other drawings (e.g., FIG. 3, FIG. 4A, etc.) and related descriptions thereof.

In some embodiments of the present disclosure, a plurality of preset frequencies are provided, and the instruction processing module 110 may accordingly output a plurality of baseband signals and a plurality of frequency tuning words corresponding to the plurality of preset frequencies, thereby providing a basis for subsequent multi-nuclide parallel imaging and noise shaping of the merged target RF signal with multi-nuclide frequency aliasing.

In some embodiments, the instruction processing module 110 may generate the baseband signal corresponding to the preset frequency according to the baseband signal parameter of the magnetic resonance sequence instruction.

In some embodiments, the instruction processing module 110 may generate the frequency tuning word corresponding to the preset frequency according to the frequency tuning parameter of the magnetic resonance sequence instruction. The frequency tuning word may be a coded value of the preset frequency, which may be expressed in binary or other forms.

For example, if MRI is performed using the 1H nuclide, the magnetic resonance sequence instruction may include the resonance frequency of the 1H nuclide, and the corresponding FTW may be a binary code corresponding to the resonance frequency. As another example, if MRI is performed using the 1H nuclide and the Na nuclide, the magnetic resonance sequence instruction may include the resonance frequency of the 1H nuclide and the resonance frequency of the Na nuclide. One frequency tuning word output by the instruction processing module 110 may be a binary code corresponding to the resonance frequency of the 1H nuclide, and the other frequency tuning word output by the instruction processing module 110 may be a binary code corresponding to the resonance frequency of the Na nuclide.

In some embodiments, the instruction processing module 110 may determine a corresponding frequency tuning word based on a center frequency of the emission signal.

The center frequency of the emission signal refers to a center frequency of emission signal that the device 100 intends to emit through an emission coil (e.g., an emission coil 150). The center frequency refers to a frequency of a center point between two half-power points after the signal passes through a filter (e.g. a bandpass filter or a band elimination filter).

In some embodiments, the magnetic resonance sequence instruction may include a layer selection parameter selected by the user. The layer selection parameter refers to a spatial positioning parameter of a magnetic resonance signal. For example, in MRI, the magnetic resonance signal acquired by a receiving coil may include information of the entire layer. The magnetic resonance signal needs to be spatially encoded such that the acquired magnetic resonance signal may include the spatial positioning information, and then decoded through mathematical conversion, and thus the magnetic resonance signal may be distributed to each pixel. In some embodiments, the layer selection parameter may include a layer spacing and a layer thickness. MRI may include a plurality of scanning layers. The layer spacing refers to a distance between two adjacent scanning layers of the plurality of scanning layers. The layer thickness refers to a thickness of a single scanning layer of the plurality of scanning layers. In some embodiments, the center frequency of the emission signal may affect the FTW. For example, when the center frequency of the emission signal increases, the corresponding FTW may also increase. Merely by way of example, if the format of the FTW is a 32-bit fixed-point number, the relationship between the FTW and the center frequency may be expressed as FTW=2\hat{ }32*IF/F_{clk}, where the FTW denotes the frequency tuning word, IF denotes the center frequency, and Folk denotes the operating frequency of digital signal processing inside the device. In some embodiments, when the magnetic resonance device scans a specific position, the center frequency of the emission signal may be adjusted when the layer selection parameter is selected. When the center frequency is adjusted, the corresponding FTW may also change. The instruction processing module 110 may determine an actual center frequency of the emission signal based on the layer selection parameter (e.g., the layer spacing and the layer thickness) selected by the user, and determine the corresponding FTW based on the actual center frequency. The actual center frequency refers to a center frequency obtained by adjustment during layer selection.

In some embodiments, the magnetic resonance sequence instruction may include a magnetic field intensity of the magnetic resonance device selected by the user. For example, the magnetic field intensity of the magnetic resonance device may be 1.5 T, 3 T, 5 T, 7 T, 9.4 T, etc. In some embodiments, an actual magnetic field intensity of the magnetic resonance device may be different from a preset magnetic field intensity. For example, when the selected preset magnetic field intensity is 1.5 T, the actual magnetic field intensity may be greater than or less than 1.5 T (e.g., because of the normal deviation of the magnetic field raising process). For example, the actual magnetic field intensity may be 1.505 T. When the magnetic field intensity changes, the change in the magnetic field intensity may cause the center frequency of the emission signal to change. For example, the greater the magnetic field intensity, the higher the center frequency of the emission signal. Furthermore, the FTW may also change. Accordingly, the instruction processing module 110 may determine the center frequency by determining the actual magnetic field intensity based on the magnetic field intensity of the magnetic resonance device selected by the user, and determine the corresponding FTW based on the center frequency.

In some embodiments, the actual center frequency of the emission signal may be determined according to the layer selection parameter selected by the user, and the actual magnetic field intensity and/or the actual center frequency may be determined according to the magnetic field intensity of the magnetic resonance device selected by the user, which may be performed by a host computer (e.g., the host computer 101), or by a field programmable gate array (FPGA) (e.g., an FPGA integrated in the device 100). If the actual center frequency and/or the actual magnetic field intensity are determined by the host computer, the device 100 can directly obtain the actual center frequency and/or the actual magnetic field intensity from the host computer, and determine the corresponding FTW based on the actual center frequency and/or the actual magnetic field intensity. For example, the magnetic resonance sequence instruction may include the actual center frequency, and the instruction processing module 110 may determine the corresponding FTW based on the actual center frequency in the magnetic resonance sequence instruction.

In some embodiments, the coefficient generation module 120 may be configured to output a noise filter coefficient based on the FTW (i.e., the FTW corresponding to the preset frequency output by the instruction processing module 110).

The noise filter coefficient refers to a parameter used by a noise shaping unit (e.g., a noise shaping unit 131) when noise shaping is performed, and can determine filtering characteristics of the noise shaping unit. For example, the noise filter coefficient may adjust a gain or attenuation degree of the noise shaping unit 131 at different preset frequencies. In some embodiments, the coefficient or the weight of a filter in the noise shaping unit (e.g., the noise shaping unit 131) may be set as the noise filter coefficient. More descriptions regarding the noise shaping unit may be found in the present disclosure below.

In some embodiments, the coefficient generation module 120 may determine and output the noise filter coefficient based on the FTW in various feasible ways, such as by looking up a table (e.g., a frequency index coefficient table), by historical experience, by using a preset algorithm (e.g., a preset mathematical formula, a pre-trained machine learning model, etc.).

In some embodiments, the coefficient generation module 120 may be configured to determine the noise filter coefficient based on the FTW and one or more system configuration parameters of the magnetic resonance device.

The one or more system configuration parameters of the magnetic resonance device may include the nuclide type. As can be seen from the foregoing, different types of nuclides have different resonance frequencies. Therefore, when MRI is performed using different types of nuclides, the instruction processing module 110 may output an FTW corresponding to the resonance frequency of the nuclide. That is, the FTW output by the instruction processing module 110 may be related to the nuclide type. Accordingly, the coefficient generation module 120 may determine the noise filter coefficient based on the FTW and the nuclide type. For example, the coefficient generation module 120 may determine the noise filter coefficient based on the FTW and the nuclide type through historical experience, looking up a table, or using the preset algorithm, etc.

The one or more system configuration parameters of the magnetic resonance device may include the magnetic field intensity. As can be seen from the foregoing, the instruction processing module 110 may determine the actual magnetic field intensity and determine the corresponding FTW based on the actual magnetic field intensity. That is, the FTW output by the instruction processing module 110 may be related to the magnetic field intensity. Accordingly, the coefficient generation module 120 may determine the noise filter coefficient based on the FTW and the magnetic field intensity. For example, the coefficient generation module 120 may determine the noise filter coefficient based on the FTW and the magnetic field intensity through historical experience, looking up a table (e.g., the frequency index coefficient table), or using the preset algorithm, etc.

In some embodiments, the coefficient generation module 120 may determine the noise filter coefficient through the frequency index coefficient table based on the FTW and/or the one or more system configuration parameters of the magnetic resonance device.

In some embodiments, the frequency index coefficient table may include a preset correspondence between various FTWs and corresponding noise filter coefficients.

In some embodiments, the frequency index coefficient table may be obtained by performing a simulation test using a filter configuration tool. For example, a corresponding filter cutoff frequency, order, and filter type may be selected according to various FTWs or preset frequencies, the corresponding noise filter coefficient may be calculated and generated using the filter configuration tool of MATLAB, the filtering effect may be evaluated using the simulation test, and noise filter coefficients with better filtering effect may be selected to establish the preset correspondence between the FTWs and the corresponding noise filter coefficients, thereby generating the frequency index coefficient table. In some embodiments, the frequency index coefficient table may be determined based on historical data. For example, various FTWs and corresponding noise filter coefficients may be obtained from historical operation or running data of the device as reference data, and the frequency index coefficient table may be determined based on the reference data. In some embodiments, partial data (e.g., a noise filter coefficient with the optimal filtering effect may be selected from a plurality of historical noise filter coefficients corresponding to each of the FTWs) may be selected from the historical data as the reference data, and the frequency index coefficient table may be determined based on the selected reference data.

In some embodiments of the present disclosure, the noise filter coefficient may be determined through the frequency index coefficient table based on the FTW, which can achieve fast matching of the FTW and the noise filter coefficient, and relatively quickly determine suitable parameters for noise shaping, thereby improving the operating efficiency of the device. When multi-nuclide parallel imaging is performed, the time for the device to switch between corresponding operation modes can also be reduced.

In some embodiments, the coefficient generation module 120 may determine the noise filter coefficients through the preset algorithm based on the FTW and/or the one or more system configuration parameters of the magnetic resonance device.

In some embodiments, the preset algorithm may include a trained first machine learning model. An input of the first machine learning model may include the FTW and/or the one or more system configuration parameters of the magnetic resonance device. The one or more system configuration parameters may include the nuclide type and/or the magnetic field intensity. The one or more system configuration parameters may be digitized. An output of the first machine learning model may include a corresponding noise filter coefficient.

The first machine learning model may be obtained by training an initial machine learning model based on multiple sets of first training samples with training labels. One set of first training samples may include sample FTWs and/or one or more sample system configuration parameters and corresponding sample noise filter coefficients. The sample noise filter coefficients may be the training labels. Specifically, the first training samples with the labels may be input into the initial machine learning model to obtain output results of the initial machine learning model. Parameters of the initial machine learning model may be updated through training until a trained intermediate machine learning model satisfies a preset condition, and a trained first machine learning model may be obtained. The preset condition may be that a loss function is less than a preset threshold, the loss function converges, or a count of training times reaches a preset threshold.

In some embodiments, the first machine learning model may include a deep neural network model (DNN), etc.

In some embodiments, each set of first training samples may correspond to an optimal noise filter coefficient. The optimal noise filter coefficient may be obtained through the simulation test or an evaluation model (e.g., the machine learning model). For example, a plurality of noise filter coefficients may be input into the evaluation model, and the evaluation model may output corresponding evaluation results (e.g., output a score and a grade (e.g., excellent, good, and medium) of each of the plurality of noise filter coefficients). The optimal noise filter coefficient may be determined based on the evaluation result. Alternatively, the evaluation model may also directly output the optimal filter coefficient.

In some embodiments, the preset algorithm may include a preset mathematical formula. The preset mathematical formula may be an expression indicating a relationship between the FTW and/or the one or more system configuration parameters of the magnetic resonance device and the noise filter coefficient. The coefficient generation module 120 may calculate the noise filter coefficient using the preset mathematical formula based on the FTW and/or the one or more system configuration parameters of the magnetic resonance device.

In some embodiments, the preset mathematical formula may be obtained through the simulation test or the learning model.

In some embodiments, the preset algorithm (the first machine learning model and/or the preset mathematical formula) may be obtained based on the historical data. For example, various FTWs and one or more corresponding noise filter coefficients may be obtained based on the historical operation or running data of the device, and the preset mathematical formula may be derived based on different FTWs and the corresponding noise filter coefficients. As another example, partial data (e.g., a noise filter coefficient with the optimal filtering effect may be selected from a plurality of historical noise filter coefficients corresponding to each of the FTWs) may be selected from the historical operation or running data as the first training samples to train the first machine learning model.

The first machine learning model trained with the historical data as the first training samples and the first machine learning model trained with the data obtained through the experiment or the evaluation model as the first training samples may be different in model output or effect. That is, if the same sample FTW is input to the first machine learning model trained with the historical data as the first training samples and the first machine learning model trained with the data obtained through the experiment or the evaluation model as the first training samples, the output noise filter coefficients may be different. In some embodiments, the noise filter coefficients output by the first machine learning model trained with the historical data as the first training samples and the first machine learning model trained with the data obtained through the experiment or the evaluation model as the first training samples may be evaluated, and the first machine learning model (e.g., a first machine learning model of which the output result is closer to a true noise filter coefficient corresponding to the sample FTW, or a first machine learning model with a higher score after the output result is input into the evaluation model) with a better output result may be used as a final first machine learning model. The final first machine learning model may be configured to determine the noise filter coefficient based on the FTW and/or the one or more system configuration parameters of the magnetic resonance device.

In some embodiments, the pulse generation module 130 may be configured to output a target RF signal based on the baseband signal and the FTW (i.e., the baseband signal and the FTW corresponding to the preset frequency output by the instruction processing module 110), and the noise filter coefficient (i.e., the noise filter coefficient output by the coefficient generation module 120).

In some embodiments, the pulse generation module 130 may determine the target RF signal in various ways such as modeling, noise shaping, etc. In some embodiments, the pulse generation module 130 may determine the target RF signal by using a signal output model based on the baseband signal, the FTW, and the noise filter coefficient.

In some embodiments, the signal output model may be a second machine learning model, such as the DNN.

In some embodiments, the signal output model may be trained by a large number of second training samples with labels. The second training samples may include sample baseband signals, sample FTWs, and sample noise filter coefficients. The labels may include corresponding sample target RF signals. The second training samples and the labels may include the baseband signals, open source RF signals, and the corresponding FTWs and noise filter coefficients obtained in various ways such as historical data, networks, and manual experience.

In some embodiments, the pulse generation module 130 may output the target RF signal corresponding to the FTW based on the baseband signal by performing noise shaping based on the noise filter coefficient. In some embodiments, the pulse generation module 130 may be configured to generate an initial RF signal based on the baseband signal and the FTW. In some embodiments, as shown in FIG. 1, the pulse generation module 130 may include the noise shaping unit 131. The noise shaping unit 131 may be configured to output the target RF signal by performing noise shaping on the initial RF signal or an intermediate RF signal based on the noise filter coefficient. In some embodiments, the intermediate RF signal is generated by merging two or more initial RF signals output by two or more pulse generation channels. More descriptions regarding the intermediate RF signal may be found in FIGS. 4A-4D and related descriptions thereof.

The initial RF signal refers to an RF signal that is initially generated without noise shaping. The initial RF signal may be a digital RF signal.

In some embodiments, the pulse generation module 130 may generate the initial RF signal of the preset frequency through a frequency modulation technology based on the baseband signal and the FTW. For example, the pulse generation module 130 may generate an orthogonal intermediate frequency local oscillator signal based on the FTW, and generate the initial RF signal by performing frequency mixing on the baseband signal and the orthogonal intermediate frequency local oscillator signal through a frequency mixing technology. As another example, the pulse generation module 130 may generate the initial RF signal by performing digital up-conversion on the baseband signal through an up-conversion modulation technology and a digital filtering technology based on the baseband signal and the FTW. Filtering parameters in the digital filtering technology may be generated according to the FTW.

A digital-to-analog process or an analog-to-digital process usually brings a certain amount of quantization noise to the signal, and the quantization noise is generally distributed within the signal band. In order to reduce or eliminate the quantization noise as much as possible, the noise shaping unit may introduce a specific disturbance signal and interfere with the initial RF signal based on the noise filter coefficient through a noise shaping technology to move the noise out of the band, thereby reducing in-band ground noise. The noise shaping unit may achieve noise shaping through a digital noise filter, a modulation technology, etc.

In some embodiments, the noise shaping unit 131 may be the digital noise filter, such as a finite impulse response filter (FIR), a wavelet transform filter, etc. In some embodiments, the noise filter coefficient refers to a value used to define filter parameters of the digital noise filter. In some embodiments, the noise shaping unit may obtain the disturbance signal, and optimize the disturbance signal by using the characteristics of the digital noise filter that can selectively pass or suppress signal components within a specific frequency range based on the noise filter coefficient, and generate a disturbance optimization signal, thereby changing the spectral characteristics of the disturbance signal; and the noise shaping unit may further interfere with the initial RF signal based on the disturbance optimization signal to suppress the noise component in the initial RF signal, thereby moving the quantization noise in the disturbance signal out of the band and realizing noise shaping of the initial RF signal and obtaining the target RF signal.

More descriptions regarding noise shaping may be found in FIG. 7 and related descriptions thereof.

The target RF signal refers to a signal obtained after the noise shaping unit performs noise shaping on the initial RF signal. After noise shaping is performed on the initial RF signal, the quantization noise may be moved out of the band, such that the ground noise of the target RF signal may be lower than that of the initial RF signal, and the signal-to-noise ratio may be improved, thereby reducing the nonlinear performance of the digital-to-analog conversion chip in the small signal region to a certain extent, and improving the dynamic range of the output signal. In some embodiments, the target RF signal may be the digital RF signal.

In some embodiments, a count of bits of the target RF signal (e.g., 12 bits) may be less than a count of bits of the initial RF signal (e.g., 16 bits). In some embodiments, the target RF signal may be a high-bit signal of the initial RF signal after noise shaping. The high-bit signal refers to a signal composed of a specified count of bits of high-bit data (e.g., data of a count of high bits (e.g., high 12 bits) in the initial RF signal, in which the corresponding specified count of bits may be 12 bits). The high-bit signal of the initial RF signal after noise shaping may be output as the target RF signal, such that data of the small signal region that may contain noise can be removed, the dynamic range can be improved, and the amount of data that needs to be processed for subsequent digital-to-analog conversion can be reduced, thereby improving the processing efficiency, and reducing the requirements for software and hardware (e.g., a digital-to-analog conversion chip with a lower quantization resolution may be used) of digital-to-analog conversion.

In some embodiments, the target RF signal may be an analog RF signal. For example, the target RF signal may be a signal obtained by performing noise shaping and digital-to-analog conversion on the initial RF signal, or a signal obtained by performing digital-to-analog conversion on a high-bit signal.

In some embodiments, the pulse generation module 130 may include at least one pulse generation channel.

The at least one pulse generation channel refers to a channel in the pulse generation module 130 for generating an RF signal corresponding to a resonance frequency of a certain nuclide.

In some embodiments, each of the at least one pulse generation channel (e.g., pulse generation channels 210-1, 210-2, . . . , 210-n shown in FIG. 3) may correspond to a preset frequency, i.e., each of the at least one pulse generation channel may correspond to a nuclide.

In combination with the foregoing, one preset frequency may be provided, and the preset frequency may correspond to the resonance frequency of the excited nuclide. Accordingly, the pulse generation module 130 may include one pulse generation channel, and one pulse generation channel may generate an RF signal of the preset frequency based on the input baseband signal and the FTW to realize single-nuclide imaging. Alternatively, the pulse generation module 130 may include two or more pulse generation channels. One of the two or more pulse generation channels may generate the RF signal of the preset frequency based on the input baseband signal and the FTW to realize single-nuclide imaging.

In combination with the foregoing, a plurality of preset frequencies may be provided. Each of the plurality of preset frequencies may correspond to a resonance frequency of a nuclide. Accordingly, the pulse generation module 130 may include a plurality of pulse generation channels. Each of the plurality of pulse generation channels may input a baseband signal and a FTW corresponding to the pulse generation channel, and generate the RF signal of the preset frequency, thereby realizing multi-nuclide parallel imaging.

In some embodiments, the at least one pulse generation channel may include the frequency mixing link and the noise shaping unit. The frequency mixing link may be configured to receive the baseband signal and the FTW corresponding to the at least one pulse generation channel, and generate the initial RF signal based on the baseband signal and the FTW. The noise shaping unit may be configured to receive the noise filter coefficient corresponding to the at least one pulse generation channel, and perform noise shaping on the initial RF signal output by the frequency mixing link based on the noise filter coefficient, and output the target RF signal corresponding to the at least one pulse generation channel. More descriptions may be found in FIGS. 3-6 and related descriptions thereof.

In some embodiments, the pulse generation module 130 may include at least one digital-to-analog conversion unit. In some embodiments, the at least one digital-to-analog conversion unit may include a digital-to-analog converter (DAC), such as a high-speed sampling DAC with a parallel interface, a DAC with a serial interface, or the like.

In some embodiments, the pulse generation module 130 may include at least one digital-to-analog conversion unit corresponding to the at least one pulse generation channel. The at least one digital-to-analog conversion unit may be configured to perform digital-to-analog conversion on the target RF signal of the corresponding pulse generation channel.

In some embodiments, the pulse generation module 130 may include a plurality of digital-to-analog conversion units. Each of the plurality of digital-to-analog conversion units may correspond to one of the plurality of pulse generation channels of the pulse generation module 130 in one-to-one correspondence. Each of the plurality of digital-to-analog conversion units may be configured to perform digital-to-analog conversion on the target RF signal of the pulse generation channel corresponding therewith. More descriptions regarding the plurality of digital-to-analog conversion units may be found in FIG. 3 and related descriptions thereof.

In some embodiments, the pulse generation module 130 may include one digital-to-analog conversion unit. In this case, if the pulse generation module 130 includes a plurality of pulse generation channels, the plurality of pulse generation channels may be connected with the digital-to-analog conversion unit, and a plurality of target RF signals output by the plurality of pulse generation channels may be merged and sent to the digital-to-analog conversion unit. More descriptions regarding one digital-to-analog conversion unit may be found in FIG. 4A and related descriptions thereof.

In some embodiments, the pulse generation module 130 may include at least one merging unit. The at least one merging unit may correspond to two or more pulse generation channels, and may be configured to merge target RF signals output by the two or more pulse generation channels, and output a merged target RF signal. The pulse generation module 130 may also include at least one digital-to-analog conversion unit. The at least one digital-to-analog conversion unit may be connected with the at least one merging unit and configured to perform digital-to-analog conversion on the merged target RF signal. More descriptions may be found in FIG. 4B and related descriptions thereof.

In some embodiments, a time point at which the instruction processing module 110 outputs the FTW to the coefficient generation module 120 may be a first time point, a time point at which the instruction processing module 110 outputs the baseband signal and the FTW to the pulse generation module 130 may be a second time point, and the first time point may be earlier than the second time point. By setting the first time point to be earlier than the second time point, the FTW can be output to the coefficient generation module 120 as early as possible, and time can be reserved for the process of the coefficient generation module 120 generating the noise filter coefficient, such that before or at the same time when the instruction processing module 110 outputs the baseband signal and the FTW to the pulse generation module 130, the coefficient generation module 120 can output the noise filter coefficient to the pulse generation module 130, and the noise shaping unit 131 of the pulse generation module 130 can perform noise shaping on the initial RF signal according to the noise filter coefficient in time.

In some embodiments, a time point at which the coefficient generation module 120 outputs the noise filter coefficient based on the FTW may be a third time point, a time point at which the noise shaping unit 131 of the pulse generation module 130 starts to perform noise shaping on the initial RF signal based on the noise filter coefficient may be a fourth time point, and the third time point may not be later than the fourth time point. By setting the third time point not to be later than the fourth time point, the noise shaping unit 131 of the pulse generation module 130 can receive the noise filter coefficient in time before or at the same time as the pulse generation module 130 generates the initial RF signal to perform noise shaping on the initial RF signal.

In some embodiments, as shown in FIG. 1, the device 100 may further includes: an emission link 140 and the emission coil 150. The emission link 140 may be connected with an output end of the pulse generation module 130 and configured to perform signal conditioning and power amplification on the target RF signal output by the pulse generation module 130. The emission coil 150 may be connected with the emission link 140. The emission coil 150 may be configured to emit an imaging RF signal based on a signal (e.g., a signal after signal conditioning and power amplification) output by the emission link 140.

In some embodiments, the emission link 140 (Tx Chain) may include at least one of a radio frequency filter, a low noise amplifier (LNA), a power amplifier (PA), etc., for signal conditioning and power amplification. In some embodiments, an input of the emission link 140 may include the target RF signal (i.e., the target RF signal output by the pulse generation module 130), and an output of the emission link 140 may include a target RF signal after signal conditioning and power amplification.

In some embodiments, the emission coil 150 (Tx Coil) may include at least one of a multi-tuned coil, a volume coil, etc. In some embodiments, an input of the emission coil 150 may include the target RF signal after signal conditioning and power amplification, and an output of the emission coil 150 may include a corresponding imaging RF signal. The imaging RF signal refers to an RF signal emitted by the emission coil 150 after signal conditioning and power amplification are performed on the target RF signal.

In some embodiments of the present disclosure, the emission link (e.g., the emission link 140) and the emission coil (e.g., the emission coil 150) are provided for the device 100, such that signal conditioning and power amplification of the target RF signal after digital-to-analog conversion can be realized, and the imaging RF signal can be emitted outward through the emission coil, thereby providing a basis for exciting the resonance response of nuclear spins and realizing MRI.

In some embodiments of the present disclosure, the baseband signal and the FTW corresponding to the preset frequency (i.e., the resonance frequency of the nuclide) are generated by analyzing the input magnetic resonance sequence instruction. The initial RF signal of the preset frequency can be generated based on the baseband signal and the FTW, meeting the requirement of selectively utilizing at least one specific nuclide for imaging. The disturbance signal can be obtained by using the noise filter coefficient generated based on the FTW through the noise shaping technology, etc., and the disturbance signal can be optimized based on the noise filter coefficient using the digital noise filter to selectively pass or suppress the characteristics of signal components within a specific frequency range. The disturbance optimization signal can be generated, such that the spectral characteristics of the disturbance signal can be changed, the quantization noise in the disturbance signal can be moved out of the band, and the noise component in the initial RF signal can be suppressed by interfering with the initial RF signal based on the disturbance optimization signal, thereby realizing noise shaping of the initial RF signal, optimizing the quantization noise of the output target RF signal, reducing the ground noise of the in-band signal, and correspondingly improving the signal-to-noise ratio of the signal to the noise. Therefore, the nonlinear performance of the digital-to-analog conversion chip in the small signal region is reduced to a certain extent, improving the overall dynamic range. Since the field of magnetic resonance generally uses narrowband signals for excitation imaging, the requirements for the signal quality of in-band signals are higher than those for out-band signals. Therefore, the device 100 provided in some embodiments of the present disclosure can be better applied to the field of magnetic resonance, and can improve the dynamic range of the magnetic resonance RF emission signal.

It is understood that the device and the modules thereof shown in FIG. 1 can be implemented in various ways. It should be noted that the above description of the device 100 and the modules thereof is only for convenience of description and cannot limit the present disclosure to the scope of the embodiments. It can be understood that for those skilled in the art, after understanding the principle of the system, it is possible to arbitrarily combine the various modules or form a subsystem to connect with other modules without deviating from this principle. In some embodiments, the instruction processing module 110, the coefficient generation module 120, and the pulse generation module 130 disclosed in FIG. 1 can be different modules in a system, or a module can realize the functions of two or more modules mentioned above. For example, each module can share a storage module, or each module can have its own storage module. Such variations are all within the scope of protection of the present disclosure.

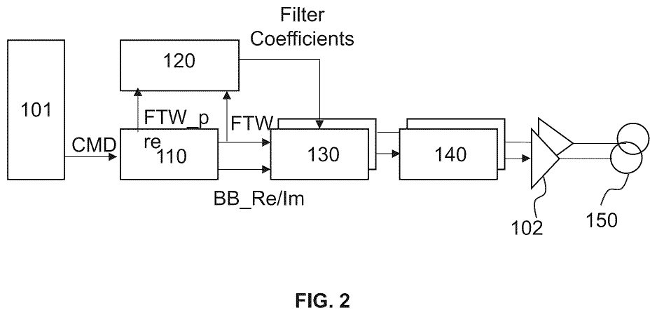

FIG. 2 is a schematic diagram illustrating an electrical principal of an exemplary device for improving a dynamic range of a magnetic resonance radio frequency (RF) emission signal according to some embodiments of the present disclosure. As shown in FIG. 2, the instruction processing module 110 may communicate with the host computer 101. The instruction processing module 110 may receive a magnetic resonance sequence instruction CMD from the host computer 101, and analyze the magnetic resonance sequence instruction CMD to generate a baseband signal BB_Re/Im, a frequency tuning word FTW, and a frequency tuning word FTW_pre corresponding to a preset frequency. The instruction processing module 110 may communicate with the pulse generation module 130. The pulse generation module 130 may receive the baseband signal BB_Re/Im and the frequency tuning word FTW from the instruction processing module 110, and generate an initial RF signal based on the baseband signal BB_Re/Im and the frequency tuning word FTW.

Meanwhile, the coefficient generation module 120 may communicate with the instruction processing module 110 and the pulse generation module 130, respectively to receive the frequency tuning word FTW and the frequency tuning word FTW_pre from the instruction processing module 110, and generate corresponding noise filter coefficients. Correspondingly, a noise shaping unit (not shown in FIG. 2) in the pulse generation module 130 may perform noise shaping on the initial RF signal based on the noise filter coefficients, and output a target RF signal to the emission link 140. The emission link 140 may perform signal conditioning on the target RF signal, perform power amplification on the target RF signal using a power amplifier 102, and send a signal after signal conditioning and power amplification to the emission coil 150, such that the emission coil 150 may emit an imaging RF signal.

FIG. 3 is a block diagram illustrating an exemplary pulse generation module according to some embodiments of the present disclosure.

In combination with the foregoing, the pulse generation module 130 may include one or more pulse generation channels. FIG. 3 illustrates a case where the pulse generation module 130 includes a plurality of pulse generation channels 210. For example, the plurality of pulse generation channels 210 may include a pulse generation channel 210-1, a pulse generation channel 210-2, . . . , a pulse generation channel 210-n, wherein n is a positive integer. It can be understood that FIG. 3 is only an example. In some embodiments, the pulse generation module 130 may include other counts (e.g., 1, 2, etc.) of pulse generation channels.

In some embodiments, as shown in FIG. 3, each of the plurality of pulse generation channels may include a frequency mixing link 132.

In some embodiments, the frequency mixing link 132 may be configured to receive the baseband signal and the FTW corresponding to each of the plurality of pulse generation channels, and generate the initial RF signal based on the baseband signal and the FTW.

The frequency mixing link 132 may be configured to implement up-conversion modulation of the baseband signal. In some embodiments, the frequency mixing link 132 may generate an orthogonal intermediate frequency local oscillator signal through a local oscillator based on the FTW, and mixing the orthogonal intermediate frequency local oscillator signal with the baseband signal through a frequency mixer to implement up-conversion modulation of the baseband signal to generate the initial RF signal.

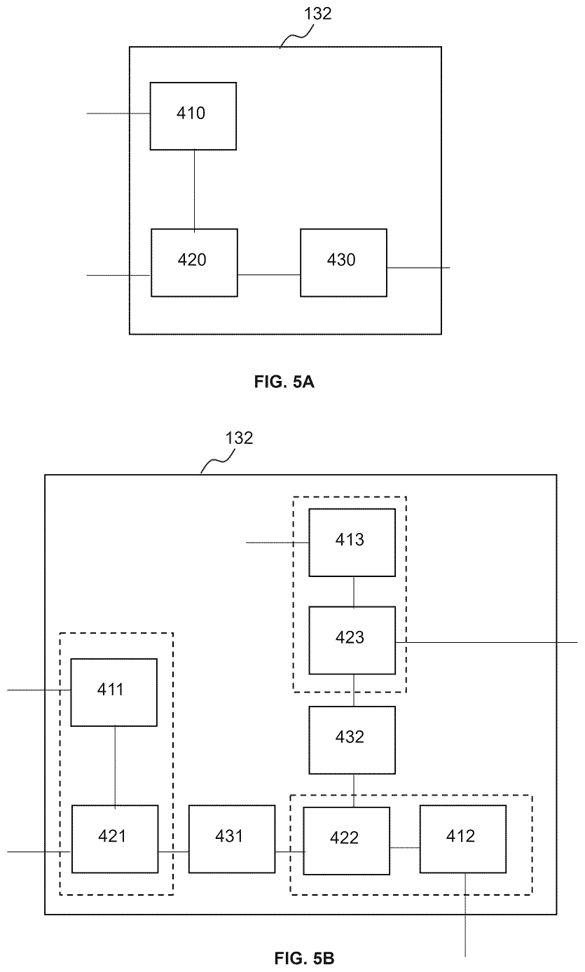

The frequency mixing link 132 may also be implemented in other ways. More descriptions may be found in FIG. 5A and FIG. 5B and related descriptions thereof.

In some embodiments, as shown in FIG. 3, each of the plurality of pulse generation channels may include the noise shaping unit 131.

The noise shaping unit 131 may be configured to receive the noise filter coefficient corresponding to the each of the plurality of pulse generation channels, and perform noise shaping on the initial RF signal or the intermediate RF signal corresponding to the each of the plurality of pulse generation channels. In some embodiments, as shown in FIG. 3, the noise shaping unit 131 may be configured to perform noise shaping on the initial RF signal output by the frequency mixing link 132 (e.g., an initial RF signal output by the up-conversion modulator 420, or a filtered initial RF signal output by the digital filter 430) based on the noise filter coefficient to output the target RF signal. More descriptions regarding the noise shaping unit may be found in FIG. 1 and FIG. 7 and related descriptions thereof.

In some embodiments, as shown in FIG. 3, the pulse generation module 130 may include a plurality of digital-to-analog conversion units 220. Each of the plurality of digital-to-analog conversion units 220 may correspond to one of the plurality of pulse generation channels 210. For example, the plurality of digital-to-analog conversion units 220 may include a digital-to-analog conversion unit 220-1, a digital-to-analog conversion unit 220-2, . . . , a digital-to-analog conversion unit 220-n, wherein n is a positive integer. The digital-to-analog conversion unit 220-1 may correspond to the pulse generation channel 210-1, the digital-to-analog conversion unit 220-2 may correspond to the pulse generation channel 210-2, . . . , and the digital-to-analog conversion unit 220-n may correspond to the pulse generation channel 210-n.

In some embodiments, after each of the plurality of pulse generation channels 210 generates a corresponding target RF signal, each of the plurality of digital-to-analog conversion units corresponding to each of the plurality of pulse generation channels 210 (e.g., the digital-to-analog conversion unit 220-1, the digital-to-analog conversion unit 220-2, . . . , and the digital-to-analog conversion unit 220-n) may perform digital-to-analog conversion on the corresponding target RF signal (i.e., convert a digital RF signal into an analog RF signal) to generate a target RF signal after digital-to-analog conversion, and input the target RF signal after digital-to-analog conversion into the emission link corresponding to the pulse generation channel.

In some embodiments, if the pulse generation module 130 includes a plurality of pulse generation channels 210 and a plurality of digital-to-analog conversion units 220, and each of the plurality of digital-to-analog conversion unit 220 (e.g., the digital-to-analog conversion unit 220-1, the digital-to-analog conversion unit 220-2, . . . , and the digital-to-analog conversion unit 220-n) corresponds one of the plurality of pulse generation channels 210 (e.g., the pulse generation channel 210-1, the pulse generation channel 210-2, . . . , and pulse generation channel 210-n) in one-to-one correspondence, a plurality of emission links and a plurality of emission coils may be provided. Each of the plurality of emission links and each of the plurality of emission coils may correspond to one digital-to-analog conversion unit, so as to perform signal conditioning and power amplification on the target RF signal after conversion of each channel, and emit the processed target RF signal. For example, each of the digital-to-analog conversion unit 220-1, the digital-to-analog conversion unit 220-2, . . . , and the digital-to-analog conversion unit 220-n may be connected with a pair of emission link and emission coil, i.e., n pairs of emission links and emission coils may be provided. More descriptions regarding the emission link and the emission coil may be found in FIGS. 1-2 and related descriptions thereof.

In some embodiments of the present disclosure, the pulse generation module is provided with the plurality of pulse generation channels, the plurality of digital-to-analog conversion units each of which corresponds to one of the plurality of pulse generation channels, the initial RF signal of the preset frequency corresponding to each pulse generation channel that is generated through the frequency mixing link of each of the plurality of pulse generation channels, and the noise shaping unit of each of the plurality of pulse generation channels that performs noise shaping on the initial RF signal based on the FTW corresponding to the pulse generation channel, the target RF signal is finally generated, which is beneficial for performing noise shaping and other optimizations (e.g., obtaining the truncated signal to optimize the data volume, see the related descriptions of FIG. 7) according to the requirements (e.g., the frequency) of each pulse generation channel, and obtaining the target RF signal with suppressed ground noise after noise shaping in each pulse generation channel, thereby emitting a plurality of imaging RF signals of different preset frequencies. Digital-to-analog conversion is performed by the plurality of digital-to-analog conversion units corresponding to the plurality of pulse generation channels, and each of the plurality of digital-to-analog conversion units corresponding to each of the plurality of pulse generation channels can be selected according to the specific requirements of the pulse generation channel to adapt to the different dynamic range and accuracy requirements of the pulse generation channel. In addition, it is easier to control the amplitude of the signal input to the plurality of digital-to-analog conversion units within the quantization range of the plurality of digital-to-analog conversion units.

It is understood that the device, modules and units shown in FIG. 3 can be implemented in various ways. It should be noted that the above description of the device 100, the modules and the units is only for convenience of description and cannot limit the present disclosure to the scope of the embodiments. It is understandable that for those skilled in the art, after understanding the principle of the system, it is possible to arbitrarily combine the modules or form a subsystem connected with other modules without deviating from this principle.

In some embodiments, the pulse generation module may include the plurality of pulse generation channels, the at least one merging unit, and the at least one digital-to-analog conversion unit. Each of the plurality of pulse generation channels may include the frequency mixing link and the noise shaping unit, and each of the plurality of pulse generation channels may generate the corresponding target RF signal. The at least one merging unit may correspond to the plurality of pulse generation channels, and may be configured to merge the target RF signals generated by the plurality of pulse generation channels and output the merged target RF signal. The at least one digital-to-analog conversion unit may be connected with the at least one merging unit and may be configured to perform digital-to-analog conversion on the merged target RF signal. In some embodiments, a count of the at least one merging unit may be the same as a count of the at least one digital-to-analog conversion unit. Each of the at least one merging unit may be connected with one of the at least one digital-to-analog conversion unit. The at least one digital-to-analog conversion unit may perform digital-to-analog conversion on the merged target RF signal output by the at least one merging unit connected therewith. The following is an example of the pulse generation module including the plurality of pulse generation channels, one merging unit, and one digital-to-analog conversion unit.

FIG. 4A is a block diagram illustrating an exemplary pulse generation module according to some embodiments of the present disclosure.

In some embodiments, as shown in FIG. 4A, the pulse generation module 130 may include a plurality of pulse generation channels 210 (e.g., the plurality of pulse generation channels 210 may include the pulse generation channels 210-1, . . . , and the pulse generation channels 210-n, wherein n is a positive integer), a merging unit 310, and a digital-to-analog conversion unit 620. The merging unit 310 may correspond to the plurality of pulse generation channels (e.g., output ends of the pulse generation channels 210-1, . . . , and the pulse generation channels 210-n may be connected with an input end of the merging unit 310). The merging unit 310 may be connected with the digital-to-analog conversion unit 620 (e.g., an output end of the merging unit 310 may be connected with an input end of the digital-to-analog conversion unit 620).

In combination with the foregoing, each of the plurality of pulse generation channels (e.g., the pulse generation channel 210-1, . . . , and the pulse generation channel 210-n) may include the frequency mixing link 132 and the noise shaping unit 131. The frequency mixing link 132 may receive a baseband signal and an FTW corresponding to the pulse generation channel, and generate an initial RF signal based on the baseband signal and the FTW. The noise shaping unit 131 may receive a noise filter coefficient corresponding to the pulse generation channel, and perform noise shaping on the initial RF signal output by the frequency mixing link 132 based on the noise filter coefficient to output a target RF signal. That is, each of the plurality of pulse generation channels may generate a corresponding target RF signal, and the plurality of pulse generation channels may output a plurality of target RF signals. The merging unit 310 may be configured to merge the plurality of target RF signals (e.g., n target RF signals output by the pulse generation channels 210-1, . . . , and the pulse generation channels 210-n) output by the plurality of pulse generation channels 210 to output a merged target RF signal. The digital-to-analog conversion unit 620 may be configured to perform digital-to-analog conversion on the merged target RF signal output by the merging unit 310, and generate a merged target RF signal after digital-to-analog conversion.

The merged target RF signal refers to a signal obtained by merging the plurality of target RF signals, and includes information of each of the plurality of target RF signals. Since each RF emission channel corresponds to a different preset frequency, each of the plurality of target RF signals to be output by each RF emission channel may be distinguished by the frequency in the emerged target RF signal.

The merging unit 310 refers to a unit for performing a merging operation on a plurality of signals. In some embodiments, the merging unit 310 may include a first digital adder, such as a parallel adder, a full adder, etc. In some embodiments, the target RF signals output by emission channel pulse generation channels may include the preset frequency. The merging unit 310 may directly merge the target RF signals output by the plurality of pulse generation channels in a digital domain, and output the merged target RF signal including the preset frequency corresponding to each of the plurality of pulse generation channels.

In some embodiments, the digital-to-analog conversion unit 620 may perform digital-to-analog conversion on the merged target RF signal to convert a digital RF signal into an analog RF signal, and generate a merged target RF signal after digital-to-analog conversion to input into an emission link.

In some embodiments, if the pulse generation module 130 includes one merging unit 310, the emission link and an emission coil may be set as a group to perform signal conditioning and power amplification on the merged target RF signal after conversion and emit a corresponding imaging RF signal (e.g., emit imaging RF signals corresponding to a plurality of preset frequencies). More descriptions regarding the emission link and the emission coil may be found in FIG. 1 and related descriptions thereof.

It should be noted that FIG. 4A takes the pulse generation module 130 including one merging unit 310 and one digital-to-analog conversion unit 620 for example. In other embodiments, different counts of merging units 310 and digital-to-analog conversion units 620 may be provided. The pulse generation module 130 may include two or more merging units 310 and two or more digital-to-analog conversion units 620, a count of the two or more merging units 310 and a count of the two or more digital-to-analog conversion units 620 being less than a count of the plurality of pulse generation channels 210. For example, FIG. 4B is a block diagram illustrating an exemplary pulse generation module according to some embodiments of the present disclosure. As shown in FIG. 4B, the pulse generation module 130 may include a plurality of pulse generation channels 210 (e.g., the plurality of pulse generation channels 210 include the pulse generation channels 210-1, . . . , a pulse generation channels 210-m, a pulse generation channels 210-(m+1), . . . , and the pulse generation channels 210-n, wherein n and m are positive integers, and n>m), two merging units (a first merging unit 311 and a second merging unit 312), and two digital-to-analog conversion units (a first digital-to-analog conversion unit 621 and a second digital-to-analog conversion unit 622). Each of the plurality of pulse generation channels (e.g., the pulse generation channels 210-1, . . . , the pulse generation channels 210-m, the pulse generation channels 210-(m+1), . . . , and the pulse generation channels 210-n) may generate a corresponding target RF signal. The first merging unit 311 may correspond to some of the plurality of pulse generation channels (e.g., the pulse generation channels 210-1, . . . , and the pulse generation channels 210-m). The first merging unit 311 may be configured to merge target RF signals generated by some of the plurality of pulse generation channels and output a first merged target RF signal. The first digital-to-analog conversion unit 621 may be connected with the first merging unit 311 and may be configured to perform digital-to-analog conversion on the first merged target RF signal. Similarly, the second merging unit 312 may correspond to the remaining of the plurality of pulse generation channels (e.g., the pulse generation channels 210-(m+1), . . . , and pulse generation channels 210-n), and the second merging unit 312 may be configured to merge target RF signals generated by the remaining of the plurality of pulse generation channels and output a second merged target RF signal. The second digital-to-analog conversion unit 622 may be connected with the second merging unit 312 and may be configured to perform digital-to-analog conversion on the second merged target RF signal. When the pulse generation module includes two or more merging units and two or more digital-to-analog conversion units, a plurality sets of emission links and emission coils may be set. A count of the plurality sets of emission links and emission coils may be the same as a count of the digital-to-analog conversion units, and each set of emission link and emission coil may correspond to one digital-to-analog conversion unit, so as to perform signal conditioning and power amplification on the target RF signals after conversion of some of the plurality of pulse generation channels, and emit the processed target RF signals.

In some embodiments of the present disclosure, by setting the plurality of pulse generation channels for the pulse generation module, merging the target RF signals output by the plurality of pulse generation channels through the merging unit, and inputting the merged target RF signal into the digital-to-analog conversion unit for digital-to-analog conversion, not only the noise shaping and other optimizations can be performed according to the requirements (e.g., the frequency) of each of the plurality of pulse generation channels (e.g., obtaining the truncated signal to optimize the data volume, see related descriptions of FIG. 7), but also the frequency division multiplexing of the plurality of target RF signals is achieved through the merging unit. Digital-to-analog conversion is performed through one digital-to-analog conversion unit, which can reduce the complexity of device implementation, reduce the power consumption of the device, and save software and hardware cost.

It should be understood that the devices, modules and units shown in FIG. 4A and FIG. 4B can be implemented in various ways. It should be noted that the above description of the device 100, the modules and the units is only for convenience of description and does not limit the present disclosure to the scope of the embodiments. It is understood that for those skilled in the art, after understanding the principle of the system, it is possible to arbitrarily combine the modules or form a subsystem connected with other modules without deviating from this principle.

Different from the merging unit 310 in FIG. 4A being connected with the digital-to-analog conversion unit 620, in some embodiments, the merging unit 310 may be connected with the noise shaping unit 131, and the noise shaping unit 131 may be connected with the digital-to-analog conversion unit 620. That is, the noise shaping unit 131 may be connected between the merging unit 310 and the digital-to-analog conversion unit 620.

In some embodiments, the pulse generation module may include a plurality of pulse generation channels, at least one merging unit, and at least one digital-to-analog conversion unit. Each of the plurality of pulse generation channels may include a frequency mixing link. The frequency mixing link may receive a baseband signal and an FTW corresponding to the pulse generation channel, and generate an initial RF signal based on the baseband signal and the FTW. That is, each of the plurality of pulse generation channels may generate a corresponding initial RF signal. Accordingly, the plurality of pulse generation channels may generate a plurality of initial RF signals. The at least one merging unit may correspond to the plurality of pulse generation channels (e.g., output ends of the plurality of pulse generation channels may be connected with an input end of one merging unit (as shown in FIG. 4A); or output ends of some of the plurality of pulse generation channels may be connected with the input end of one merging unit, and input ends of the remaining of the plurality of pulse generation channels may be connected with an input end of another merging unit (as shown in FIG. 4B)), and may be configured to merge the initial RF signals generated by the plurality of pulse generation channels connected therewith and output an intermediate RF signal. The pulse generation module may further include at least one noise shaping unit. Each of the at least one noise shaping unit may be connected with each of the at least one merging unit. The at least one noise shaping unit may be configured to receive noise filter coefficients corresponding to the plurality of pulse generation channels, perform noise shaping on the intermediate RF signals output by the at least one merging unit connected therewith based on the noise filter coefficients, and output corresponding target RF signals. Each of the at least one digital-to-analog conversion unit may be connected with each of the at least one noise shaping unit. The at least one digital-to-analog conversion unit may be configured to perform digital-to-analog conversion on the target RF signals output by the at least one noise shaping unit connected therewith. In some embodiments, a count of the at least one merging unit, a count of the at least one noise shaping unit, and a count of the at least one digital-to-analog conversion units may be the same. For example, each of the at least one merging unit may be connected with one noise shaping unit, and the noise shaping unit may be connected with one digital-to-analog conversion unit. The noise shaping unit may performs noise shaping on the intermediate RF signal output by the merging unit connected therewith, and output the corresponding target RF signal. The target RF signal may be input to the digital-to-analog conversion unit connected with the noise shaping unit to be subjected to digital-to-analog conversion by the digital-to-analog conversion unit. The following is an example in which the pulse generation module includes a plurality of pulse generation channels, one merging unit, one noise shaping unit, and one digital-to-analog conversion unit.

FIG. 4C is a block diagram illustrating an exemplary pulse generation module according to some embodiments of the present disclosure. As shown in FIG. 4C, the pulse generation module 130 may include a plurality of pulse generation channels 610 (e.g., the plurality of pulse generation channels 610 may include a pulse generation channels 610-1, . . . , and a pulse generation channels 610-n, wherein n is a positive integer), a merging unit 310, a noise shaping unit 631, and a digital-to-analog conversion unit 620. An input end of the merging unit 310 may be connected with output ends of the plurality of pulse generation channels 610. An output end of the merging unit 310 may be connected with an input end of the noise shaping unit 631. An output end of the noise shaping unit 631 may be connected with an input end of the digital-to-analog conversion unit 620.

In some embodiments, as shown in FIG. 4C, each of the plurality of pulse generation channels (e.g., the pulse generation channel 610-1, . . . , and the pulse generation channel 610-n) may include the frequency mixing link 132. The frequency mixing link 132 may receive a baseband signal and an FTW corresponding to the pulse generation channel, and generate an initial RF signal based on the baseband signal and the FTW. That is, each of the plurality of pulse generation channels may generate a corresponding initial RF signal. The merging unit 310 may correspond to the plurality of pulse generation channels 610, and may be configured to merge the initial RF signals (e.g., n initial RF signals generated by the pulse generation channels 610-1, . . . , and pulse generation channels 610-n) generated by the plurality of pulse generation channels 610, and output an intermediate RF signal. The noise shaping unit 631 may be connected with the merging unit 310, and may be configured to receive noise filter coefficients corresponding to the plurality of pulse generation channels, perform noise shaping on the intermediate RF signal output by the merging unit 310 based on the noise filter coefficients, and output a target RF signal. The digital-to-analog conversion unit 620 may be connected with the noise shaping unit 631 and may be configured to perform digital-to-analog conversion on the target radio frequency signal to generate a target radio frequency signal after conversion.

In this case, the intermediate RF signal output by the merging unit 310 refers to a signal after the plurality of initial RF signals are merged, and includes information of each of the plurality of initial RF signals. Since each RF emission channel corresponds to a different preset frequency, the initial RF signal output by each RF emission channel can be distinguished by the frequency in the intermediate RF signal. The intermediate RF signal may be a digital RF signal. Noise shaping may be performed on the intermediate RF signal by the noise shaping unit 631. The intermediate RF signal after noise shaping may be the target RF signal. The target RF signal may include preset frequency information corresponding to each of the plurality of pulse generation channels.

In some embodiments, the digital-to-analog conversion unit 620 may perform digital-to-analog conversion on the target RF signal output by the noise shaping unit 631 to convert a digital RF signal into an analog RF signal, thereby generating a target RF signal after digital-to-analog conversion to input into an emission link.

In some embodiments, as shown in FIG. 4C, the merging unit 310 of the pulse generation module 130 may be connected with the noise shaping unit 631, and the noise shaping unit 631 may be connected with the digital-to-analog conversion unit 620. In this case, the emission link and an emission coil can be set as a group to perform signal conditioning and power amplification on the target RF signal after digital-to-analog conversion output by the digital-to-analog conversion unit 620, and emit an imaging RF signal.

It should be noted that FIG. 4C takes the pulse generation module 130 including one merging unit 310, one noise shaping unit 631 and one digital-to-analog conversion unit 620 for example for illustration. In other embodiments, a count of the merging unit 310, a count of the noise shaping unit 631, and a count of the digital-to-analog conversion unit 620 may be set in different ways. The pulse generation module 130 may include two or more merging units 310, two or more noise shaping units 631, and two or more digital-to-analog conversion units 620, a count of the two or more merging units 310, a count of the two or more noise shaping units 631, and a count of the two or more digital-to-analog conversion units 620 being less than a count of the plurality of pulse generation channels 610. For example, FIG. 4D is a block diagram illustrating an exemplary pulse generation module according to some embodiments of the present disclosure. As shown in FIG. 4D, the pulse generation module 130 may include a plurality of pulse generation channels 610 (e.g., the plurality of pulse generation channels 610 may include a pulse generation channels 610-1, . . . , a pulse generation channels 610-m, a pulse generation channel 610-(m+1), . . . , and a pulse generation channels 610-n, wherein n and m are positive integers, and n>m), two merging units (the first merging unit 311 and the second merging unit 312), and two digital-to-analog conversion units (the first digital-to-analog conversion unit 621 and the second digital-to-analog conversion unit 622). Each of the plurality of pulse generation channels (e.g., the pulse generation channels 610-1, . . . , the pulse generation channels 610-m, the pulse generation channels 610-(m+1), . . . , and the pulse generation channels 210-n) may generate a corresponding initial RF signal. The first merging unit 311 may correspond to some of the plurality of pulse generation channels (e.g., the pulse generation channels 610-1, . . . , and the pulse generation channels 610-m). The first merging unit 311 may be configured to merge initial RF signals generated by some of the plurality of pulse generation channels and output a first intermediate RF signal. A first noise shaping unit 6311 may be connected with the first merging unit 311 and may be configured to receive noise filter coefficients corresponding to the plurality of pulse generation channels, and perform noise shaping on the first intermediate RF signal output by the first merging unit 311 based on the noise filter coefficients to output a first target RF signal. The first digital-to-analog conversion unit 621 may be connected with the first noise shaping unit 6311 and configured to perform digital-to-analog conversion on the first target RF signal. Similarly, the second merging unit 312 may correspond to the remaining of the plurality of pulse generation channels (e.g., the pulse generation channels 610-(m+1), . . . , and pulse generation channels 610-n), and the second merging unit 312 may be configured to merge initial RF signals generated by the remaining of the plurality of pulse generation channels and output a second intermediate RF signal. A second noise shaping unit 6312 may be connected with the second merging unit 312 and configured to receive the noise filter coefficients corresponding to the plurality of pulse generation channels, and perform noise shaping on the second intermediate RF signal output by the second merging unit 312 based on the noise filter coefficients to output a second target RF signal. The second digital-to-analog conversion unit 622 may be connected with the second merging unit 312 and may be configured to perform digital-to-analog conversion on the second target RF signal. When the pulse generation module includes two or more merging units, two or more noise shaping units, and two or more digital-to-analog conversion units, a plurality sets of emission links and emission coils may be set. A count of the plurality sets of emission links and emission coils may be the same as a count of the digital-to-analog conversion units, and each set of emission link and emission coil may correspond to one digital-to-analog conversion unit, so as to perform signal conditioning and power amplification on the target RF signals after conversion of some of the plurality of pulse generation channels, and emit the processed target RF signals. For example, as shown in the embodiment of FIG. 4D, two pairs of emission links and emission coils may be provided. One pair of two pairs of emission links and emission coils may be connected with the first digital-to-analog conversion unit 621, and the other pair of two pairs of emission links and emission coils may be connected with the second digital-to-analog conversion unit 622.

In the embodiments of the present disclosure, by setting the plurality of pulse generation channels for the pulse generation module, merging the initial RF signals output by the plurality of pulse generation channels by the merging unit, and inputting the intermediate RF signal into a noise shaping unit for noise shaping to obtain the target RF signal (i.e., the initial RF signals are merged and then noise shaping is performed), such that the count of the noise shaping unit can be reduced, thereby saving hardware resources and software resources. For example, FPGA can be reduced by about 30%.

It should be understood that the devices, modules and units shown in FIG. 4C and FIG. 4D can be implemented in various ways. It should be noted that the above description of the device 100, the modules and the units is only for convenience of description and does not limit the present disclosure to the scope of the embodiments. It is understood that for those skilled in the art, after understanding the principle of the system, it is possible to arbitrarily combine the modules or form a subsystem connected with other modules without deviating from this principle.

FIG. 5A is a block diagram illustrating an exemplary frequency mixing link according to some embodiments of the present disclosure. In some embodiments, as shown in FIG. 5A, the frequency mixing link 132 may include: a numerically controlled oscillator 410, an up-conversion modulator 420, and a digital filter 430. The numerically controlled oscillator 410 may be configured to generate a local oscillator signal based on an FTW. The up-conversion modulator 420 may be connected with the numerically controlled oscillator 410. The up-conversion modulator 420 may be configured to generate an initial RF signal based on the local oscillator signal and a baseband signal. The digital filter 430 may be connected with the up-conversion modulator 420. The digital filter 430 may be configured to filter the initial RF signal and obtain a filtered initial RF signal.

The numerically controlled oscillator 410 (NCO) may be to generate an orthogonal intermediate frequency local oscillator signal of a specified frequency. In some embodiments, the numerically controlled oscillator 410 in a pulse generation channel may generate the orthogonal intermediate frequency local oscillator signal based on the FTW corresponding to the pulse generation channel.

In some embodiments, the NCO 410 may be implemented by direct digital frequency synthesis technology (DDS), etc. For example, the NCO may include a phase accumulator, a lookup table, etc. The phase may be accumulated by the phase accumulator according to a set step value. An accumulated phase value may be multiplied by the FTW corresponding to the pulse generation channel to obtain a frequency shift. The frequency shift may be mapped to the corresponding orthogonal intermediate frequency local oscillator signal through the lookup table for output.

The up-conversion modulator 420 (MOD, Modulator) may be configured to implement frequency shift and modulation, which can be implemented by direct up-conversion modulation, digital up-conversion modulation technology, up-conversion modulation based on a phase-locked loop, etc. In some embodiments, the up-conversion modulator 420 may include a frequency mixer.

In some embodiments, the up-conversion modulator 420 in the pulse generation channel may perform frequency mixing through the frequency mixer based on a baseband signal corresponding to the pulse generation channel and the orthogonal intermediate frequency local oscillator signal output by the NCO 410, and output an initial RF signal of a preset frequency.

The digital filter 430 may be configured to filter out harmonic and stray frequency band information.

In some embodiments, the frequency mixing link 132 may include a plurality stages of NCOs 410 and up-conversion modulators 420. Each stage of the plurality stages of NCOs 410 and up-conversion modulators 420 may include one NCO and one up-conversion modulator. The plurality stages of NCOs 410 and up-conversion modulators 420 may be connected in series through the up-conversion modulator of each stage of the plurality stages of NCOs 410 and up-conversion modulators 420. In each stage of the plurality stages of NCOs 410 and up-conversion modulators 420, the NCO may generate the orthogonal intermediate frequency local oscillator signal based on the FTW corresponding to the pulse generation channel, and the up-conversion modulator may perform frequency mixing on an initial RF signal output by the previous stage of NCO 410 and up-conversion modulator 420 and the orthogonal intermediate frequency local oscillator signal output by the digital controlled oscillator of the current stage of NCO 410 and up-conversion modulator 420 to output an initial RF signal of the current stage of NCO 410 and up-conversion modulator 420. An initial RF signal output by the up-conversion modulator of the last stage of NCO 410 and up-conversion modulator 420 may be used as an output of the frequency mixing link. In some embodiments, if the frequency mixing link 132 includes the plurality stages of NCOs 410 and up-conversion modulators 420, a corresponding digital filter may be set at an input of the up-conversion modulator of each stage of the plurality stages of NCOs 410 and up-conversion modulators 420 except the first stage of NCO 410 and up-conversion modulator 420 to filter an input signal.

Merely by way of example, FIG. 5B is a block diagram illustrating another exemplary frequency mixing link according to some embodiments of the present disclosure. As shown in FIG. 5B, the frequency mixing link 132 may include three stages of NCOs and up-conversion modulators. The first stage of NOC and up-conversion modulator may include a first NCO 411 and a first up-conversion modulator 421. The second stage of NCO and up-conversion modulator may include a second NCO 412 and a second up-conversion modulator 422. The third stage of NCO and up-conversion modulator may include a third NCO 413 and a third up-conversion modulator 423. The first stage of NOC and up-conversion modulator and the second stage of NOC and up-conversion modulator may be connected in series through the second up-conversion modulator 422. The second stage of NOC and up-conversion modulator and the third stage of NOC and up-conversion modulator may be connected in series through the third up-conversion modulator 423. A first digital filter 431 may be provided at an input of the second up-conversion modulator 422. A second digital filter 432 may be provided at an input of the third up-conversion modulator 423. In some embodiments, the first NCO 411 may generate an orthogonal intermediate frequency local oscillator signal based on the FTW corresponding to the pulse generation channel. The first up-conversion modulator 421 may generate a first initial RF signal based on the orthogonal intermediate frequency local oscillator signal and the baseband signal. The first digital filter 431 may filter the first initial RF signal. Further, the second up-conversion modulator 422 may perform frequency mixing on a filtered first initial RF signal and the orthogonal intermediate frequency local oscillator signal output by the second NCO 412, and output a second initial RF signal. The second digital filter 432 may filter the second initial RF signal. Further, the third up-conversion modulator 423 may perform frequency mixing on a filtered second-level initial RF signal and an orthogonal intermediate frequency local oscillator signal output by the third NCO 413, and output a third initial RF signal. The third initial RF signal may be used as an output of the frequency mixing link 132.

In some embodiments of the present disclosure, the NCO, the up-conversion modulator, and the digital filter may be provided for the device 100. The NCO can provide the high-precision orthogonal intermediate frequency local oscillator signal, providing a basis for the generation of the initial radio frequency signal. The up-conversion modulator can modulate a low-frequency baseband signal into an intermediate frequency signal. The digital filter can filter out the harmonic and stray frequency band information, thereby improving the signal quality of the initial RF signal.

It should be understood that the devices, modules and units shown in FIG. 5A and FIG. 5B can be implemented in various ways. It should be noted that the above description of the device 100, the modules and the units is only for convenience of description and does not limit the present disclosure to the scope of the embodiments. It is understood that for those skilled in the art, after understanding the principle of the system, it is possible to arbitrarily combine the modules or form a subsystem connected with other modules without deviating from this principle. For example, the frequency mixing link 132 may include a numerically controlled oscillator 410 and an up-conversion modulator 420.

Taking the plurality of pulse generation channels shown in FIG. 4A for example, an exemplary pulse generation module is provided below to describe in detail the specific embodiment of the plurality of pulse generation channels.

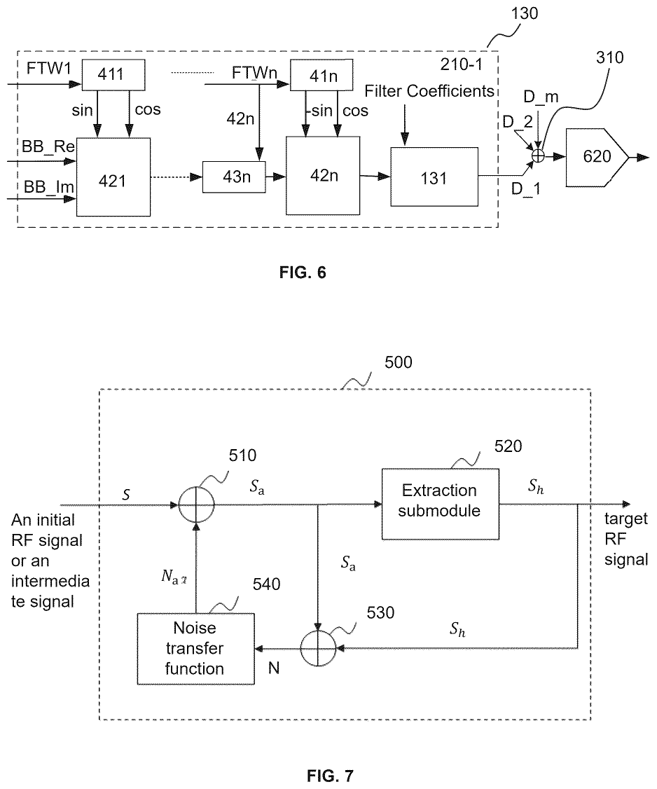

FIG. 6 is schematic diagram illustrating an electrical principal of an exemplary pulse generation module according to some embodiments of the present disclosure. In some embodiments, as the pulse generation module 130 shown in FIG. 6, in a pulse generation channel (e.g., the pulse generation channel 210-1), a first NCO (e.g., the first NCO 411) may receive a FTW1 corresponding to the pulse generation channel 210-1, generate orthogonal intermediate frequency local oscillator signals sin and cos, and send the orthogonal intermediate frequency local oscillator signals sin and cos to a first up-conversion modulator (e.g., the first up-conversion modulator 421). The first up-conversion modulator 421 may also receive a baseband signal BB_Re and a baseband signal BB_Im corresponding to the pulse generation channel 210-1, and perform frequency mixing on the orthogonal intermediate frequency local oscillator signals sin and cos, the baseband signal BB_Re and the baseband signal BB_Im to generate a first initial RF signal (not shown in FIG. 6), and send the initial RF signal to a second digital filter (not shown in FIG. 6), such that the second digital filter may filter the first initial RF signal, thereby facilitating signal processing of a next stage of NCO and up-conversion modulator. Meanwhile, the first digital control oscillator 411 may also send a second FTW to a second NCO (not shown in FIG. 6).

Similarly, an n-th digital filter 43n may receive and filter an (n−1)th initial RF signal, and send a filtered signal to an n-th up-conversion modulator 42n for an n-th time of signal frequency mixing. An n-th NCO 41n may receive an n-th FTWn to generate orthogonal intermediate frequency local oscillator signals-sin and cos, and send the orthogonal intermediate frequency local oscillator signals-sin and cos to the n-th up-conversion modulator 42n. The n-th up-conversion modulator 42n may receive a filtered (n−1)th initial RF signal, and perform frequency mixing on the orthogonal intermediate frequency local oscillator signals-sin and cos and the (n−1)th initial RF signal, and output an n-th initial RF signal (not shown in FIG. 6) as an output of a frequency mixing link in the pulse generation channel 210-1.

Referring to FIG. 6, a noise shaping unit (e.g., the noise shaping unit 131) may receive the n-th initial RF signal and a noise filter coefficient corresponding to the pulse generation channel 210-1, perform noise shaping on the initial RF signal based on the noise filter coefficient, and output a target RF signal D_1 of the pulse generation channel 210-1. Then a merging unit (e.g., the merging unit 310) may merge target RF signals D_1, D_2, . . . , D_m, etc. output by the plurality of pulse generation channels, and output a merged target RF signal to a digital-to-analog conversion unit (e.g., the digital-to-analog conversion unit 620), such that the digital-to-analog conversion unit 620 may output an RF signal.

FIG. 7 is a logic block diagram illustrating an exemplary hardware or software of a noise shaping unit according to some embodiments of the present disclosure.

In some embodiments, a noise shaping unit may be further configured to: perform noise shaping on an initial RF signal or an intermediate RF signal through a noise shaping filter based on a noise filter coefficient. In some embodiments, a count of bits of the target RF signal is less than a count of bits of the intermediate RF signal. In some embodiments, when a pulse generation module adopts the structure of FIG. 4A or FIG. 4B, the noise shaping unit may be configured to: perform noise shaping on the initial RF signal through the noise shaping filter based on the noise filter coefficient. In some embodiments, when the pulse generation module adopts the structure of FIG. 4C or FIG. 4D, the noise shaping unit may be configured to: perform noise shaping on the intermediate RF signal through the noise shaping filter based on the noise filter coefficient.

The noise shaping filter refers to a digital filter used to perform shaping on noise. A noise transfer function corresponding to the noise shaping filter may describe the filtering characteristics of the noise shaping filter, and the shape and the performance of the noise transfer function may be affected by the setting of the noise filter coefficient. For example, the noise shaping filter may include a finite impulse response filter (FIR), a wavelet transform filter, etc. Accordingly, the noise transfer function of the FIR may be usually expressed by the noise filter coefficient. For example, the noise transfer function of H (z) of an N-order FIR filter may be expressed as:

$$H ( z ) = {\sum }_{k = 0}^{N - 1} h ( k ) * {z}^{- n} \qquad ( 1 )$$

wherein h(k) denotes a set of noise filter coefficients, and z denotes a variable represented in a z domain of the noise transfer function.

In some embodiments, one or more parameters of the noise shaping filter may correspond to a resonance frequency of an excited nuclide. The one or more parameters of the noise shaping filter may include, but are not limited to, a filter order, a center frequency of the filter, a cutoff frequency, etc. In some embodiments, the order of the noise shaping filter may correspond to a count of the excited nuclide. For example, when MRI is performed using a single nuclide (e.g., a 1H nuclide), the noise shaping filter may be a four-order filter. As another example, when MRI is performed using dual nuclides (e.g., the 1H nuclide and a 13C nuclide), the noise shaping filter may be a nine-order filter. In some embodiments, when MRI is performed using different types of nuclides, the order corresponding to the noise shaping filter may be adaptively adjusted. The higher the order of the noise shaping filter, the more the noise shaping filter can suppress noise in an initial RF signal. For example, when MRI is performed using a large number of nuclides or the type of nuclide used has a large ground noise, a noise shaping filter of higher order may be selected correspondingly to improve the noise reduction effect and the signal-to-noise ratio, thereby reducing the nonlinear performance of a digital-to-analog conversion chip in a small signal region to a large extent, and further improving the dynamic range of an output signal.

Noise shaping may be performed by flexibly using noise shaping filters with different parameters (e.g. the filter order) based on the count and/or the type of the excited nuclide, such that the noise shaping effect and the signal-to-noise ratio can be improved while reasonably consuming hardware and software resources, thereby reducing the nonlinear performance of the digital-to-analog conversion chip in the small signal region to a certain extent, and improving the dynamic range of the output signal.

In some embodiments, a pulse generation module may include two or more noise shaping units (as shown in FIG. 4A and FIG. 4B). One or more parameters of at least one of two or more noise shaping filters corresponding to the two or more noise shaping units may be different from one or more parameters of other noise shaping filters.

For example, parallel imaging may be performed using three nuclides, such as the 1H nuclide, the 13C nuclide, and the 19F nuclide. Each of a plurality of pulse generation channels of the pulse generation module may correspond to one nuclide. The pulse generation module may include three noise shaping units, such as a first noise shaping unit, a second noise shaping unit, and a third noise shaping unit. The first noise shaping unit may receive a first noise filter coefficient (a noise filter coefficient corresponding to the 1H nuclide) corresponding to one pulse generation channel, and perform noise shaping on a first initial RF signal through a first noise shaping filter. The second noise shaping unit may receive a second noise filter coefficient (a noise filter coefficient corresponding to the 13C nuclide) corresponding to one pulse generation channel, and perform noise shaping on a second initial RF signal through a second noise shaping filter. The third noise shaping unit may receive a third noise filter coefficient (a noise filter coefficient corresponding to the 19F nuclide) corresponding to one pulse generation channel, and perform noise shaping on a third initial RF signal through a third noise shaping filter. In this case, since the resonance frequencies of different types of nuclides are different, the parameters of the corresponding noise shaping filters may also be different. In order to consider both the consumption of the hardware/software resources and shaping effect (the signal-to-noise ratio), the orders of the first noise shaping filter, the second noise shaping filter, and the third noise shaping filter may be different or partially different from each other. MRI may be performed using three nuclides (e.g., the 1H nuclide, the 13C nuclide, and the 19F nuclide), the noise shaping filters of different orders can be used because the ground noise corresponding to the three nuclides may be different. For example, a noise shaping filter with a higher order can be selected for a nuclide with larger ground noise, and a noise shaping filter with a lower order can be selected for a nuclide with smaller ground noise, which can not only ensure the overall noise reduction effect and improve the dynamic range of the output signal, but also consider the consumption of the hardware/software resources.

In some embodiments, the noise shaping unit may obtain a disturbance signal through methods such as random number generation, quantization error simulation, low-bit data interception, etc., and input the disturbance signal into the noise shaping filter. The noise shaping filter may filter the disturbance signal based on the noise filter coefficient corresponding to each of the plurality of pulse generation channels. The noise shaping unit may determine and output a target RF signal based on an initial RF signal or an intermediate RF signal and the filtered disturbance signal.

In some embodiments, noise shaping may include: obtaining a signal to be optimized; obtaining the disturbance signal based on the signal to be optimized, the disturbance signal being a preset count of low bits in the signal to be optimized (e.g., 4 low bits in the signal to be optimized, and in this case, the corresponding preset count of bits is 4 bits); inputting the disturbance signal into the noise shaping filter, and the noise shaping filter outputting a disturbance optimization signal; obtaining an optimized signal based on the initial RF signal or the intermediate RF signal and the disturbance optimization signal; and obtaining the target RF signal based on the optimized signal. In the process of noise shaping, the preset count of low bits may be obtained from the signal to be optimized as the disturbance signal, and the disturbance signal may have a strong correlation with quantization noise in the signal to be optimized. The spectral characteristics of the disturbance signal may be changed by using the characteristics of the digital noise filter that can selectively pass or suppress signal components within a specific frequency range, and the quantization noise in the disturbance signal may be moved out of the band, thereby optimizing the disturbance signal, generating the disturbance optimization signal, and then interfering with the initial RF signal based on the disturbance optimization signal to suppress the noise component in the initial RF signal.

In some embodiments, noise shaping may include at least one round of shaping. In one round of shaping: the signal to be optimized of a current round may be obtained. If the current round of shaping is a first round of shaping, the signal to be optimized may be the initial RF signal or an intermediate RF signal; if the current round of shaping is not the first round of shaping, the signal to be optimized may be an optimized signal of a previous round of shaping. A disturbance signal of the current round of shaping may be obtained based on the signal to be optimized; the disturbance signal may be input into the noise shaping filter, and the noise shaping filter may output the disturbance optimization signal; and the optimized signal of the current round of shaping may be obtained based on the initial RF signal or the intermediate RF signal and the disturbance optimization signal.

In some embodiments, noise shaping may be an iterative process. For example, a plurality rounds of shaping may be performed. After the first round of noise shaping is started, in each subsequent round of shaping, shaping may be continued based on the signal output in the previous round. A condition for terminating the iteration may include reaching a preset count of iterations, the amplitude of the disturbance signal being less than a preset amplitude, reaching a set time, etc. In some embodiments, noise shaping may be performed continuously.

In some embodiments, as shown in FIG. 7, the noise shaping unit may include a first adder 510, an extraction submodule 520, and a second adder 530.

The first adder 510 may include at least one of a full adder and an accumulator. In some embodiments, the first adder 510 may input an initial RF signal S (or an intermediate signal) and a disturbance optimization signal Nₐ of the current round, and output an optimized signal Sₐ of the current round. When the current round is the first round of shaping, the disturbance optimization signal Nₐ of the current round may be zero, the first adder 510 may input the initial RF signal S and the zero disturbance optimization signal Nₐ. The output optimized signal Sₐ of the current round may be equal to the initial RF signal S. In some embodiments, the optimized signal Sₐ of the current round output by the first adder 510 may be used as the input of the next round.

In some embodiments, in the current round of noise shaping process 500, a signal to be optimized Sₐ of the current round may be obtained based on an output of the first adder 510.

The signal to be optimized refers to a RF signal that needs to be optimized in the current round of noise shaping.

In some embodiments, the signal to be optimized and the initial RF signal may have the same count of bits. For example, if the initial RF signal output by a frequency mixing link is 16 bits, the signal to be optimized in the current round may all be 16 bits.

In some embodiments, a disturbance signal N of the current round may be obtained based on the signal to be optimized Sₐ.

The disturbance signal refers to noise, such as quantization noise, Gaussian white noise, etc. In some embodiments, a preset count of low bits in the signal to be optimized Sₐ may be obtained as the disturbance signal N of the current round based on the signal to be optimized Sₐ. The preset count of bits refers to a specified count of bits smaller than a count of bits of the initial RF signal, such as 4 bits, 5 bits, etc. For example, if the signal to be optimized in the current round is 16 bits and the preset count of bits is 4 bits, the disturbance signal may include the low 4 bits of the signal to be optimized, and the remaining high 12 bits of data may be the high-bit data of the signal to be optimized. In some embodiments, different nuclides may correspond to different preset count of bits. That is, the preset count of bits may be determined according to the type of nuclide to be used.

In some embodiments, the noise shaping unit may obtain high-bit data Sₕ of the signal to be optimized Sₐ through the extraction submodule 520, and determine the disturbance signal N through the second adder 530 based on the signal to be optimized Sₐ and the high-bit data Sₕ.

The extraction submodule 520 may include at least one of a rounding operation, a shift operation, setting mask to perform bitwise AND operation, etc. For example, the signal to be optimized Sₐ may be shifted to the right by a preset count of bits to obtain high-bit data Sₕ. As another example, a mask having the same count of bits as the signal to be optimized may be set, the low-order data of the preset count of bits in the mask may be set to 0, and the remaining high-order data may be set to 1. The bitwise AND operation is performed on the mask and the signal to be optimized Sₐ to remove low-order data that is zero to obtain the high-order data Sₕ.

In some embodiments, the noise shaping unit may add a preset count of zeros to the low bit of the high-bit data Sₕ, or shift the low bit to the left by a preset count of bits, and calculate a difference between a value after adding a preset count of zeros or shifting to the left and the signal to be optimized Sₐ through the second adder 530 to determine the disturbance signal N. The specific embodiment of the second adder 530 may be found in the embodiment of the first adder 510.

Since the low-bit data may contain more quantization noise, while the high-bit data contains the main information component, the preset count of low bits in the signal to be optimized Sₐ may be extracted as the disturbance signal N of the current round.

In some embodiments, the disturbance signal N may be input into the noise shaping filter, and the noise shaping filter may filter the disturbance signal N through a noise transfer function 540 to output the disturbance optimization signal Nₐ.

The disturbance optimized signal refers to a signal obtained by filtering and optimizing the disturbance signal.

Since the noise filter coefficient corresponding to each of the plurality of pulse generation channels determines the shape and the performance of the noise transfer function 540, the noise shaping filter may filter the disturbance signal through the noise transfer function 540, which can change the frequency characteristics of the disturbance noise, and suppress the in-band noise related to a preset frequency.

In some embodiments, the optimized signal Sₐ of the current round may be obtained as the input of the next round by adding the initial RF signal S with the disturbance optimization signal Nₐ through the first adder 510.

The optimized signal refers to a RF signal of which the noise performance is optimized after the current round of noise shaping. In some embodiments, the optimized signal refers to a signal obtained by adding the initial RF signal with the disturbance optimization signal.

By addition, the disturbance optimization signal may interfere with the initial RF signal to suppress the noise component in the initial RF signal, such that the optimized signal has a lower ground noise than the signal to be optimized, thereby improving the signal-to-noise ratio.

In some embodiments, noise shaping may further include: generating a target RF signal for output based on the optimized signal obtained by at least one round of shaping. In some embodiments, generating a target RF signal based on the optimized signal obtained by at least one round of shaping may include: obtaining a truncated signal based on the optimized signal obtained by at least one round of shaping, and using the truncated signal as the target RF signal.

The truncated signal refers to a signal that truncates or limits the amplitude of an original signal to a certain range. In some embodiments, the truncated signal is high-bit data in the optimized signal obtained by at least one round of shaping. In some embodiments, the truncated signal may be obtained by removing a preset count of low-bit data in the optimized signal, rounding off the preset count of low-bit data, rounding off function, etc.

The truncated signal may be obtained based on the optimized signal obtained by at least one round of shaping, and the truncated signal may be output as the target RF signal. Since the data of the small signal region that may contain noise is removed, the truncated signal including the high-bit data may retain the main information, such that the effective count of bits of the digital-to-analog conversion unit may be concentrated on processing the truncated signal, which improves the resolution and accuracy of the signal, improves the dynamic range, and also realizes data compression of the optimized signal, thereby reducing the amount of data for subsequent processing, reducing the requirements for the software and hardware of the digital-to-analog conversion (e.g., a digital-to-analog conversion chip with a lower quantization resolution may be used, etc.), and saving the software and hardware resources.

In some embodiments, after the optimized signal of the current round is obtained in each round of shaping, the truncated signal may be obtained and the truncated signal may be output as the target RF signal.

In each round of shaping, the quantization noise (i.e., the disturbance signal) may be continuously filtered based on the optimization in the previous round, thereby further optimizing the target RF signal.

It should be understood that the device, modules and units shown in FIG. 7 can be implemented in various ways. It should be noted that the above description of the device 100, the modules and the units is only for convenience of description and cannot limit the present disclosure to the scope of the embodiments. It is understood that for those skilled in the art, after understanding the principle of the system, it is possible to arbitrarily combine the modules or form a subsystem connected with other modules without deviating from this principle.

In some embodiments, the pulse generation module 130 may include a switch. The switch may be connected with the noise shaping unit and configured to connect or block a connection between the noise shaping unit and the at least one pulse generation channel. In some embodiments, the switch may be a single-pole double-throw switch. By adjusting the throwing direction of the single-pole double-throw switch, the connection between the noise shaping unit and the at least one pulse generation channel may be connected or blocked. For example, referring to FIG. 3, a single-pole double-throw switch may be provided before or after the noise shaping unit 131 of each of the at least one pulse generation channel. When the single-pole double-throw switch is thrown to one end, the connection between the noise shaping unit 131 and the at least one pulse generation channel may be connected. In this case, the noise shaping unit 131 may perform noise shaping on the initial RF signal output by the frequency mixing link 132, and the target RF signal after noise shaping may be input to the at least one digital-to-analog conversion unit 220. When the single-pole double-throw switch is thrown to the other end, the connection between the noise shaping unit 131 and the at least one pulse generation channel may be blocked. In this case, the initial RF signal output by the frequency mixing link 132 may be directly input to the at least one digital-to-analog conversion unit 220 without noise shaping.

By setting the single-pole double-throw switch and adjusting the throwing direction of the single-pole double-throw switch to connect or block the connection between the noise shaping unit and the at least one pulse generation channel, the use flexibility of the device can be improved. For example, when parallel imaging is performed using multiple nuclides, the connection between each noise shaping unit and the corresponding pulse generation channel may be be selected to be connected or blocked according to an actual situation (e.g., the nuclide type, etc.). In some embodiments, when the ground noise of the nuclide is less than a preset value, the single-pole double-throw switch of the pulse generation channel corresponding to the nuclide may be blocked. The preset value may be a specific value or a value interval, which may be determined according to the ground noise of the nuclide. For example, the noise level corresponding to a nuclide with low ground noise may be set as the preset value. For example, taking three pulse generation channels as an example, a single-pole double-throw switch may be connected before the noise shaping unit contained in each of the three pulse generation channels. When MRI is performed using the 1H nuclide, the 13C nuclide, and the 19F in the three pulse generation channels, respectively, the single-pole double-throw switch of the pulse generation channel corresponding to the 13C nuclide and the 19F nuclide may be connected, and the single-pole double-throw switch of the pulse generation channel corresponding to the 1H nuclide may be locked.

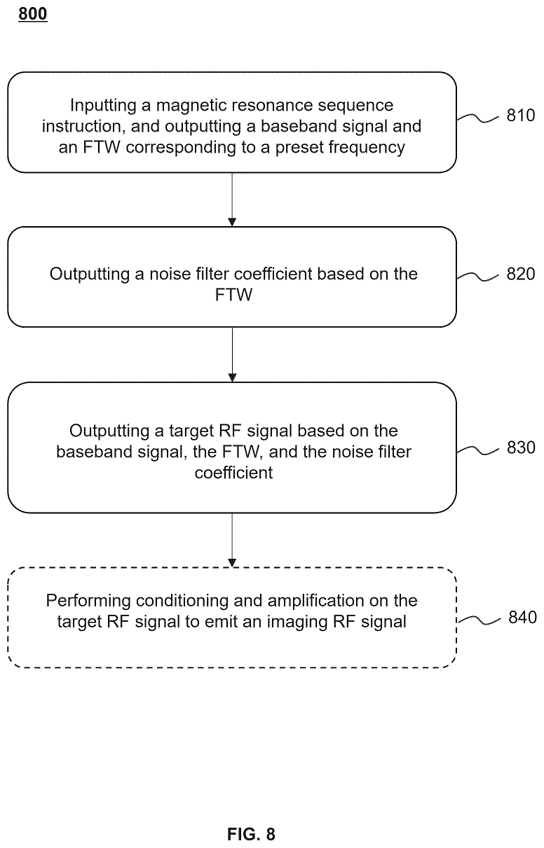

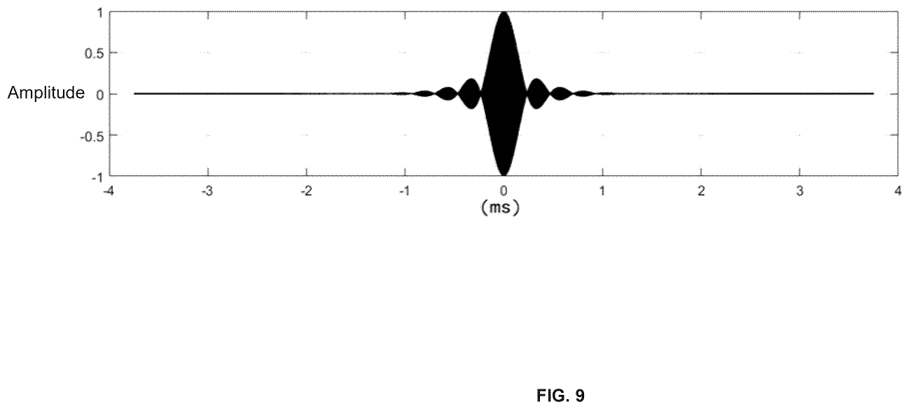

FIG. 8 is a flowchart illustrating an exemplary method for improving a dynamic range of a magnetic resonance radio frequency (RF) emission signal according to some embodiments of the present disclosure. A process 800 may be executed by a processor. In some embodiments, the processor may include one or more hardware processors, such as a microcontroller, a microprocessor, a reduced instruction set computer (RISC), a central processing unit (CPU), a graphics processing unit (GPU), a digital signal processor (DSP), a field programmable gate array (FPGA), an advanced RISC machine (ARM), any circuit or processor capable of performing one or more functions, or any combination thereof.

The process 800 may include the following operations.

In 810, a magnetic resonance sequence instruction may be input, and output a baseband signal and an FTW corresponding to a preset frequency may be output.

In some embodiments, one or more preset frequencies may be provided. Each of the one or more preset frequencies may correspond to a resonance frequency of a nuclear.

In 820, noise filter coefficient may be output based on the FTW.

In some embodiments, the noise filter coefficient may be determined based on the FTW through a frequency index coefficient table. In some embodiments, the noise filter coefficient may be determined based on the FTW and/or one or more system configuration parameters of a magnetic resonance device through a preset algorithm (e.g., a trained machine learning model, and a preset mathematical formula).

In 830, a target RF signal may be output based on the baseband signal, the FTW, and the noise filter coefficient.

In some embodiments, an initial RF signal may be generated based on the baseband signal and the FTW. In some embodiments, the initial RF signal of the preset frequency may be generated through at least one pulse generation channel based on the baseband signal and the FTW.

In some embodiments, the at least one pulse generation channel may include a frequency mixing link.

In some embodiments, the frequency mixing link may receive the baseband signal and the FTW corresponding to the at least one pulse generation channel, and generates the initial RF signal of the preset frequency based on the baseband signal and the FTW.

In some embodiments, the frequency mixing link may include: an NCO configured to generate a local oscillator signal based on the FTW; an up-conversion modulator configured to generate the initial RF signal based on the local oscillator signal and the baseband signal; and a digital filter configured to filter the initial RF signal.

In some embodiments, noise shaping may be performed on the initial RF signal based on the noise filter coefficient to output the target RF signal.

In some embodiments, noise shaping may be performed on the initial RF signal through a noise shaping filter based on the noise filter coefficient.

In some embodiments, the at least one pulse generation channel may further include a noise shaping unit. The noise shaping unit may receive the noise filter coefficient corresponding to the at least one pulse generation channel, and perform noise shaping on the initial RF signal output by the frequency mixing link in the at least one pulse generation channel based on the noise filter coefficient to output the target RF signal.

In some embodiments, one or more pulse generation channels may be provided. Each of the one or more pulse generation channels may correspond to a preset frequency. In some embodiments, the noise shaping units of the one or more pulse generation channels may respectively perform noise shaping on the initial RF signals generated by the frequency mixing link in the one or more pulse generation channels to output one or more target RF signals.

In some embodiments, noise shaping may include at least one round of shaping. In one round of shaping: a signal to be optimized of the current round may be obtained, when the current round is the first round of shaping, the signal to be optimized may be the initial RF signal, and when the current round is not the first round of shaping, the signal to be optimized may be an optimized signal of the previous round of shaping; a disturbance signal of the current round may be obtained based on the signal to be optimized; the disturbance signal being a preset count of low-bit data in the signal to be optimized; the disturbance signal may be input into the noise shaping filter, the noise shaping filter may output a disturbance optimization signal; and an optimized signal of the current round may be obtained based on the initial RF signal and the disturbance optimization signal. Noise shaping may further include: the target RF signal may be generated for output based on an optimized signal obtained after at least one round of shaping.

In some embodiments, each of the one or more pulse generation channels may output to a corresponding digital-to-analog conversion unit. The digital-to-analog conversion unit may perform digital-to-analog conversion on the target RF signal of the corresponding pulse generation channel.

In some embodiments, each of the one or more pulse generation channels may output to a merging unit. The merging unit may add the target RF signals of the one or more of pulse generation channels to output a merged target RF signal. In some embodiments, digital-to-analog conversion may be performed the merged target RF signal by the at least one digital-to-analog conversion unit.

In some embodiments, the process 800 may further includes operation 840.

In 840, conditioning and amplification may be performed on the target RF signal to emit an imaging RF signal.

In some embodiments, signal conditioning and power amplification may be performed the target RF signal through an emission link; and the imaging RF signal may be emitted through an emission coil based on a signal output by the emission link.

More descriptions regarding the preset frequency, the FTW, noise shaping, etc., may be found in other figures above (e.g., FIGS. 1-7, etc.) and related descriptions thereof.

It should be noted that the above description of the process 800 is only for example and explanation, and does not limit the scope of application of the present disclosure. For those skilled in the art, various modifications and changes can be made to the process 800 under the guidance of the present disclosure. However, such modifications and changes are still within the scope of the present disclosure.

In some embodiments, one or more embodiments of the present disclosure further provide a magnetic resonance imaging (MRI) method based on multi-channel emission. The MRI method may include: receiving a magnetic resonance sequence instruction, determining a baseband signal and a frequency tuning word (FTW) corresponding to a preset frequency, and determining a noise filter coefficient; determining at least one imaging RF signal based on the baseband signal, the FTW, and the noise filter coefficient; exciting a target portion of a detection object (e.g., a patient) using the imaging RF signal, wherein the imaging RF signal can be emitted by an emission coil to the target portion of the detection object; acquiring a magnetic resonance signal of the target portion; and reconstructing the magnetic resonance signal to obtain a magnetic resonance image.

The imaging RF signal may be emitted by driving the emission coil by a plurality of RF power amplifiers (e.g., the power amplifier PA in FIG. 2). In some embodiments, the plurality of RF power amplifiers may be activated alternately in a manner of frequency division multiplexing during an imaging sequence, such that the emission coil may form RF fields with different emission frequencies.

The emission coil may be connected with at least one emission link. The at least one emission link may obtain digital RF signals (e.g., the target RF signal) corresponding to multiple nuclides. The digital RF signals corresponding to multiple nuclides may be merged by frequency division multiplexing to generate a merged signal (e.g., the merged target RF signal). The merged target RF signal may be sent to the plurality of RF power amplifiers after digital-to-analog conversion. The emission coil may be a multi-tuned coil.

In order to further illustrate the effectiveness of the technical solution disclosed in the present disclosure, the schematic diagrams of time domain and/or frequency domain responses after different processing operations in some embodiments of the present disclosure may be compared using a simulation signal to illustrate the effects that may be achieved by the technical solution.

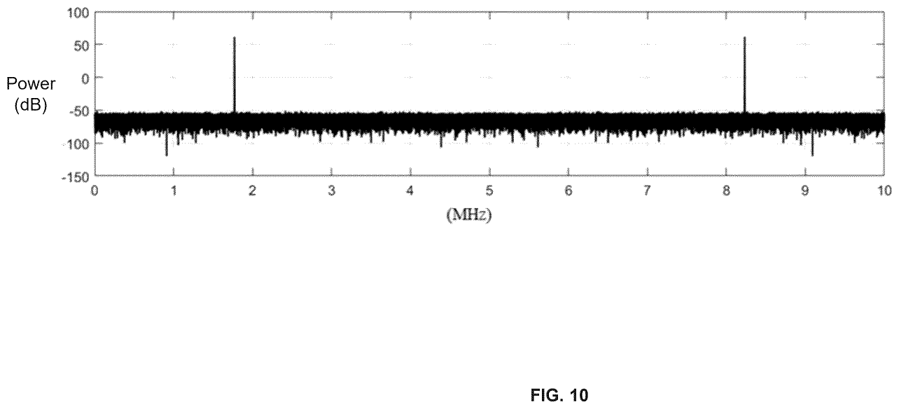

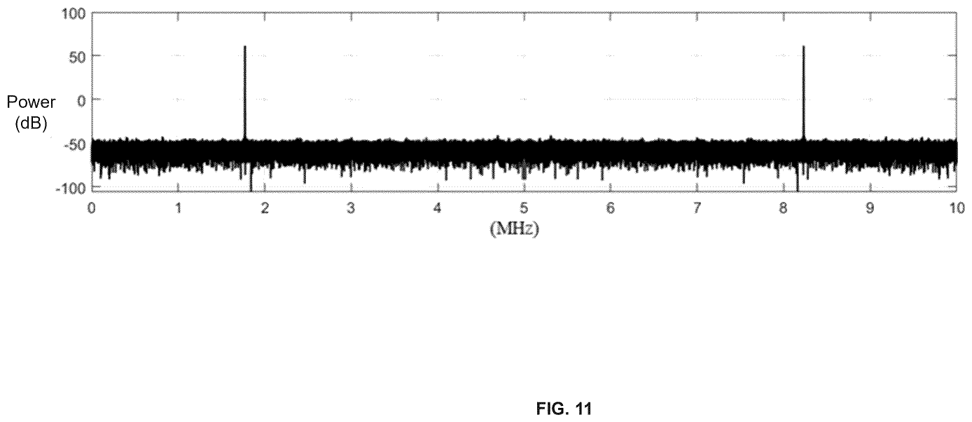

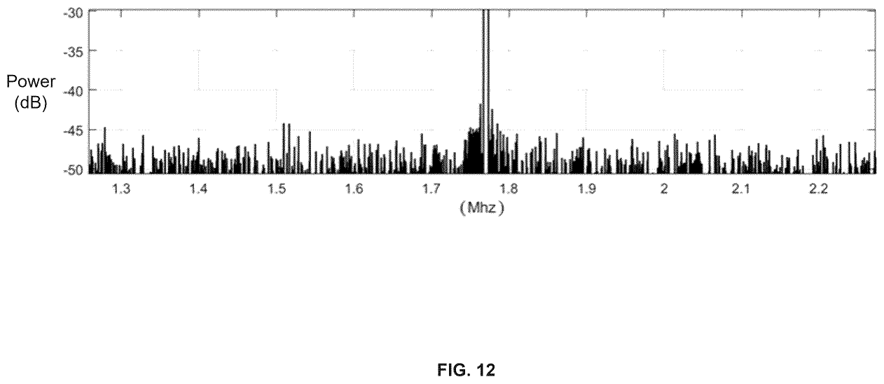

FIG. 9 and FIG. 10 are schematic diagrams illustrating an exemplary time domain response and an exemplary frequency domain response of an analog simulation signal according to some embodiments of the present disclosure. FIG. 11 is a schematic diagram illustrating an exemplary frequency domain response of a digital simulation signal according to some embodiments of the present disclosure. The digital simulation signal refers to a signal after quantization of the analog simulation signal in FIG. 9 and FIG. 10. The digital simulation signal may be understood as an initial RF signal in some embodiments of the present disclosure. In FIG. 9 and FIG. 10, a 1.77 Mhz sinusoidal wave (Gaussian white noise added) may be used as the analog simulation signal, and a modulation period of the sinusoidal wave may be 1 ms, including 16 zero points. FIG. 9 is a diagram illustrating the time domain response of the analog simulation signal, wherein the horizontal axis denotes time, the unit is ms, and the vertical axis denotes amplitude. FIG. 10 is a diagram illustrating the frequency domain response of the analog simulation signal, wherein the horizontal axis denotes frequency, the unit is MHz, the vertical axis denotes power, and the unit is dB. The quantization resolution for quantizing the analog simulation signal may be 16 bits, i.e., the digital simulation signal in FIG. 11 may be 16 bits. In FIG. 11, the horizontal axis denotes frequency, the unit is MHz, the vertical axis denotes power, and the unit is dB. FIG. 12 is a schematic diagram illustrating partial enlargement of an exemplary frequency domain response of a digital simulation signal according to some embodiments of the present disclosure.

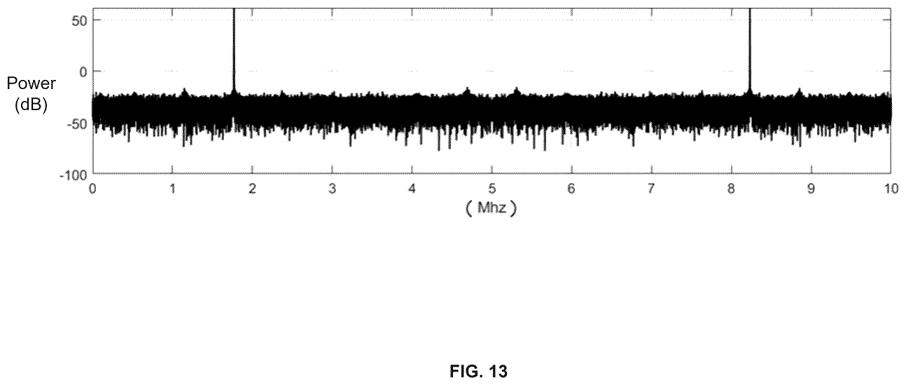

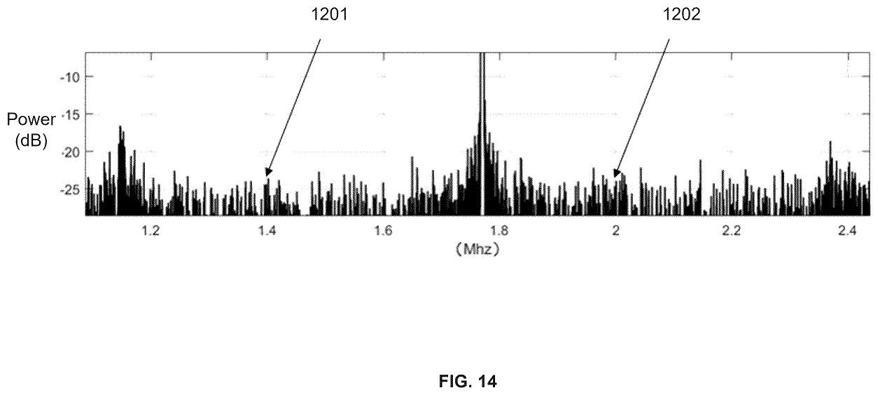

FIG. 13 is a schematic diagram illustrating an exemplary frequency domain response of a truncated signal of a digital simulation signal according to some embodiments of the present disclosure. The truncated signal of the digital simulation signal refers to a truncated signal output by truncating the digital simulation signal in FIG. 11. The truncated signal may be 12 bits, and the frequency response of the truncated signal may be shown in FIG. 13. The truncated signal of the digital simulation signal may be understood as a signal that is directly truncated and output without noise shaping of the initial RF signal in some embodiments of the present disclosure. In FIG. 13, the horizontal axis denotes frequency, the unit is MHz, the vertical axis denotes power, and the unit is dB. FIG. 14 is a schematic diagram illustrating partial enlargement of an exemplary frequency domain response of a truncated signal of a digital simulation signal according to some embodiments of the present disclosure.

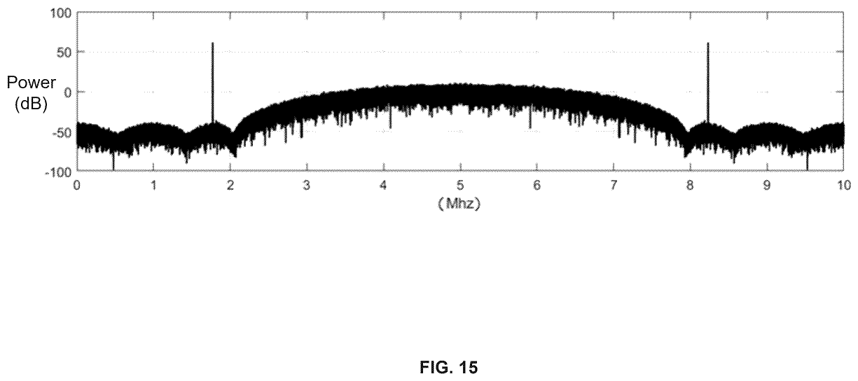

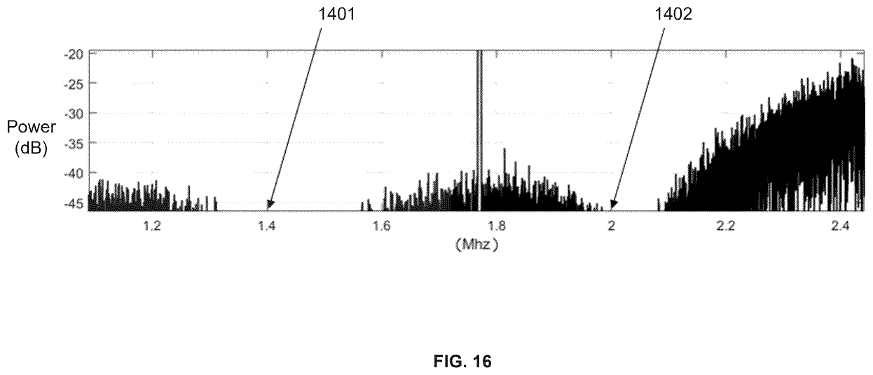

FIG. 15 is a schematic diagram illustrating an exemplary frequency domain response of a truncated signal output after noise shaping is performed on a digital simulation signal according to some embodiments of the present disclosure. Outputting the truncated signal after noise shaping of the digital simulation signal refers to performing noise shaping on the digital simulation signal in FIG. 11, and performing truncating and outputting after noise shaping. The truncated signal output after noise shaping of the digital simulation signal may be understood as the target RF signal described in some embodiments of the present disclosure. In FIG. 15, the truncated signal may be 12 bits, the horizontal axis denotes the frequency, the unit is MHz, the vertical axis denotes power, and the unit is dB. FIG. 16 is a schematic diagram illustrating partial enlargement of an exemplary frequency domain response of a truncated signal output after noise shaping is performed on a digital simulation signal according to some embodiments of the present disclosure.

Comparing FIGS. 11-12 with FIG. 10, it can be seen that the ground noise of the quantized input signal in FIGS. 11-12 in the frequency domain is increased compared to the ground noise of the analog signal in FIG. 10, and the ground noise is relatively constant. This ground noise is an error caused by the quantization operation, i.e., quantization noise. Comparing FIGS. 13-14 with FIGS. 15-16, it can be seen that the truncated signal output after noise shaping is concave in the frequency spectrum of the region where the resonance frequency of the nuclide is located compared to the truncated signal output before noise shaping, and the in-band (the frequency range involved in the imaging RF signal in the scanning sequence of the magnetic resonance sequence instruction) ground noise is suppressed. For example, a point 1201 and a point 1202 in FIG. 14 may be compared with a point 1401 and a point 1402 in FIG. 16, respectively. Referring to the horizontal coordinates 1.4 MHz and 2 MHz (the operating frequencies of two different nuclides), and the power indicated by the vertical coordinate, it can be more clearly seen that the ground noise the truncated signal after noise shaping is suppressed below-45 dB at the frequencies of 1.4 MHz and 2 MHz. In summary, the device or the method for improving the dynamic range of the magnetic resonance RF emission signal provided in some embodiments of the present disclosure can not only meet the requirements of selectively using at least one specific nuclide for imaging, but also optimize the quantization noise of the output target RF signal, the ground noise of the signal can be lower, and the signal-to-noise ratio can be correspondingly improved, thereby improving the overall dynamic range.

One or more embodiments of the present disclosure further provide a multi-nuclide magnetic resonance imaging (MRI) system. The system may include an imaging device and an RF emission unit. The RF emission unit may be connected with the imaging device. The RF emission unit may include a host computer and the device 100 as described in any one of the above embodiments. The host computer may be configured to send a magnetic resonance sequence instruction. The device 100 may be configured to receive the magnetic resonance sequence instruction and emit an imaging RF signal corresponding to the magnetic resonance sequence.

In some embodiments, a user may input requirements or parameters of MRI through an interactive interface provided by the host computer. The host computer may output the requirements or parameters of MRI in the form of magnetic resonance sequence instruction. The device 100 may input the magnetic resonance sequence instruction, processes the magnetic resonance sequence instruction through the method described in any one of the above embodiments, and emit an imaging RF signal corresponding to the magnetic resonance sequence instruction.

The beneficial effects that may be brought about by the embodiments of the present disclosure include but are not limited to the following content.
(1) By analyzing the input magnetic resonance sequence instruction, the baseband signal and the FTW corresponding to the preset frequency (i.e., the resonance frequency of the nuclide) can be generated; the initial RF signal of the preset frequency can be generated based on the baseband signal and the FTW to meet the requirements of selectively using at least one specific nuclide for imaging. The noise filter coefficient generated based on the FTW can also be used through noise shaping technology. For example, the disturbance signal can be obtained, the disturbance signal can be optimized based on the characteristics of selectively passing or suppressing the signal components within a specific frequency range using the digital noise filter based on the noise filter coefficient, and the disturbance optimization signal can be generated, thereby changing the spectral characteristics of the disturbance signal, moving the quantization noise in the disturbance signal out of the band, and then interfering with the initial RF signal based on the disturbance optimization signal to suppress the noise component in the initial RF signal to realize noise shaping of the initial RF signal, such that the quantization noise of the output target RF signal is optimized, the ground noise of the in-band signal is lower, and the signal-to-noise ratio is correspondingly improved. Therefore, the nonlinear performance of the digital-to-analog conversion chip in the small signal region is reduced to a certain extent, which is conducive to improving the overall dynamic range. Since the field of magnetic resonance generally uses narrowband signals for excitation imaging, the requirements for the signal quality of in-band signals are higher than those for the signal quality of out-band signals. Accordingly, the device 100 and the process 800 provided in some embodiments of the present disclosure can be better applied to the field of magnetic resonance and improve the dynamic range of the magnetic resonance RF signal.
(2) The noise filter coefficient is determined through the frequency index coefficient table based on the FTW, which can achieve rapid matching between the FTW and the noise filter coefficient, and determine the appropriate parameters for noise shaping more quickly, thereby improving the operating efficiency of the device. When multi-nuclide parallel imaging is performed, the time for the device to switch between corresponding operation modes can also be reduced.
(3) When a plurality of preset frequencies are provided, the instruction processing module accordingly outputs a plurality of baseband signals and FTWs corresponding to the plurality of preset frequencies, thereby providing a basis for subsequent multi-nuclide parallel imaging and noise shaping of the merged target RF signal with multi-nuclide frequency aliasing.
(4) The NCO, the up-conversion modulator, and the digital filter are provided for the device 100. The NCO can provide the high-precision orthogonal intermediate frequency local oscillator signal, providing a basis for generating the initial RF signal. The up-conversion modulator can modulate a low-frequency baseband signal into an intermediate frequency signal. The digital filter can filter out harmonic and stray frequency band information, thereby improving the signal quality of the initial RF signal.
(5) By providing a plurality of pulse generation channels and a plurality of digital-to-analog conversion units corresponding to the plurality of pulse generation channels for the pulse generation module, generating the initial RF signal of the preset frequency corresponding to each of the plurality of pulse generation channel through the frequency mixing link of each of the plurality of pulse generation channels, and performing noise shaping on the initial RF signal by the noise shaping unit of each of the plurality of pulse generation channels based on the FTW corresponding to the pulse generation channel to finally generate the target RF signal, noise shaping and other optimizations (e.g., obtaining the truncated signal to optimize the data volume, see the related descriptions of FIG. 7) can be performed according to the requirements of each pulse generation channel (e.g., the frequency), and the target RF signal with the suppressed ground noise after noise shaping can be obtained in each pulse generation channel, so as to emit a plurality of imaging RF signals of different preset frequencies. By performing digital-to-analog conversion with the digital-to-analog conversion unit corresponding to each of the plurality of pulse generation channels, the digital-to-analog conversion unit of each of the plurality of pulse generation channels can be selected according to the specific requirements of the pulse generation channel to adapt to different dynamic ranges and accuracy requirements of each pulse generation channel. In addition, it is easier to control the amplitude of the signal input to the digital-to-analog conversion unit within the quantization range of the digital-to-analog conversion unit.
(6) By setting the plurality of pulse generation channels for the pulse generation module, the target RF signals output by the plurality of pulse generation channels are added through the merging unit, and the merged target RF signal obtained by the addition is input into the digital-to-analog conversion unit for digital-to-analog conversion, such that noise shaping and other optimizations (e.g., obtaining the truncated signal to optimize the data volume, see the related descriptions of FIG. 7) can be performed according to the requirements (e.g. frequency) of each of the plurality of pulse generation channels, and frequency division multiplexing of a plurality of target RF signals can be realized through the merging unit. The digital-to-analog conversion is performed through the digital-to-analog conversion unit, which can reduce the complexity of device implementation, further reducing the power consumption of the device, and saving software and hardware cost.
(7) Since the noise filter coefficient corresponding to each of the plurality of pulse generation channels determines the shape and the performance of the noise transfer function, the noise shaping filter filters the disturbance signal through the noise transfer function, thereby changing the frequency characteristics of the disturbance noise, and suppressing the in-band noise related to the preset frequency.
(8) By obtaining the preset count of low-bit data from the signal to be optimized as the disturbance signal, the disturbance signal with a strong correlation with the quantization noise in the signal to be optimized can be obtained. By adding the initial RF signal with the disturbance optimization signal, the disturbance optimization signal can interfere with the initial RF signal to suppress the noise component in the initial RF signal, such that the optimized signal has lower ground noise than the signal to be optimized, thereby improving the signal-to-noise ratio.
(9) The truncated signal is obtained based on the optimized signal obtained by at least one round of shaping, and the truncated signal is output as the target RF signal. Since the data of the small signal region that may contain noise is removed, the truncated signal including the high-bit data retains the main information, such that the effective count of bits of the digital-to-analog conversion unit is concentrated on processing the truncated signal, which improves the resolution and accuracy of the signal, improves the dynamic range, and also realizes data compression of the optimized signal, thereby reducing the amount of data for subsequent processing, reducing the requirements (e.g., the digital-to-analog conversion chip with a lower quantization resolution can be used, etc.) for the software and hardware of digital-to-analog conversion, and saving software and hardware resources.
(10) In each of at least one round of noise shaping, the quantization noise (i.e., the disturbance signal) is continuously filtered based on the optimization obtained in the previous round, such that the target RF signal can be further optimized.

Having thus described the basic concepts, it may be rather apparent to those skilled in the art after reading this detailed disclosure that the foregoing detailed disclosure is intended to be presented by way of example only and is not limiting. Various alterations, improvements, and modifications may occur and are intended to those skilled in the art, though not expressly stated herein. These alterations, improvements, and modifications are intended to be suggested by this disclosure and are within the spirit and scope of the exemplary embodiments of this disclosure.

Moreover, certain terminology has been used to describe embodiments of the present disclosure. For example, the terms “one embodiment,” “an embodiment,” and “some embodiments” mean that a particular feature, structure, or feature described in connection with the embodiment is included in at least one embodiment of the present disclosure. Therefore, it is emphasized and should be appreciated that two or more references to “an embodiment” or “one embodiment” or “an alternative embodiment” in various portions of this specification are not necessarily all referring to the same embodiment. Furthermore, the particular features, structures, or features may be combined as suitable in one or more embodiments of the present disclosure.

Furthermore, the recited order of processing elements or sequences, or the use of numbers, letters, or other designations therefore, is not intended to limit the claimed processes and methods to any order except as may be specified in the claims. Although the above disclosure discusses through various examples what is currently considered to be a variety of useful embodiments of the disclosure, it is to be understood that such detail is solely for that purpose and that the appended claims are not limited to the disclosed embodiments, but, on the contrary, are intended to cover modifications and equivalent arrangements that are within the spirit and scope of the disclosed embodiments. For example, although the implementation of various parts described above may be embodied in a hardware device, it may also be implemented as a software only solution, e.g., an installation on an existing server or mobile device.

Similarly, it should be appreciated that in the foregoing description of embodiments of the present disclosure, various features are sometimes grouped together in a single embodiment, figure, or description thereof for the purpose of streamlining the disclosure aiding in the understanding of one or more of the various embodiments. This method of disclosure, however, is not to be interpreted as reflecting an intention that the claimed subject matter requires more features than are expressly recited in each claim. Rather, claimed subject matter may lie in less than all features of a single foregoing disclosed embodiment.

In some embodiments, numbers describing the number of ingredients and attributes are used. It should be understood that such numbers used for the description of the embodiments use the modifier “about”, “approximately”, or “substantially” in some examples. Unless otherwise stated, “about”, “approximately”, or “substantially” indicates that the number is allowed to vary by +20%. Correspondingly, in some embodiments, the numerical parameters used in the description and claims are approximate values, and the approximate values may be changed according to the required features of individual embodiments. In some embodiments, the numerical parameters should consider the prescribed effective digits and adopt the method of general digit retention. Although the numerical ranges and parameters used to confirm the breadth of the range in some embodiments of the present disclosure are approximate values, in specific embodiments, settings of such numerical values are as accurate as possible within a feasible range.

For each patent, patent application, patent application publication, or other materials cited in the present disclosure, such as articles, books, specifications, publications, documents, or the like, the entire contents of which are hereby incorporated into the present disclosure as a reference. The application history documents that are inconsistent or conflict with the content of the present disclosure are excluded, and the documents that restrict the broadest scope of the claims of the present disclosure (currently or later attached to the present disclosure) are also excluded. It should be noted that if there is any inconsistency or conflict between the description, definition, and/or use of terms in the auxiliary materials of the present disclosure and the content of the present disclosure, the description, definition, and/or use of terms in the present disclosure is subject to the present disclosure.

Finally, it should be understood that the embodiments described in the present disclosure are only used to illustrate the principles of the embodiments of the present disclosure. Other variations may also fall within the scope of the present disclosure. Therefore, as an example and not a limitation, alternative configurations of the embodiments of the present disclosure may be regarded as consistent with the teaching of the present disclosure. Accordingly, the embodiments of the present disclosure are not limited to the embodiments introduced and described in the present disclosure explicitly.

1. A device for improving a dynamic range of a magnetic resonance radio frequency (RF) emission signal, comprising:
an instruction processing module, configured to receive a magnetic resonance sequence instruction and output a baseband signal and a frequency tuning word corresponding to a preset frequency;
a coefficient generation module, configured to output, based on the frequency tuning word, a noise filter coefficient; and
a pulse generation module, configured to output a target RF signal based on the baseband signal, the frequency tuning word, and the noise filter coefficient.

2. The device of claim 1, wherein the preset frequency corresponds to a resonance frequency of an excited nuclide.

3. The device of claim 1, wherein the instruction processing module is configured to output, based on the magnetic resonance sequence instruction, two or more baseband signals and frequency tuning words corresponding to two or more preset frequencies.

4. The device of claim 1, wherein the pulse generation module includes at least one noise shaping unit configured to perform, based on the noise filter coefficient, noise shaping on an initial RF signal or an intermediate RF signal to output the target RF signal, wherein the initial RF signal is generated based on the baseband signal and the frequency tuning word.

5. The device of claim 4, wherein a count of bits of the target RF signal is less than a count of bits of the initial RF signal and the count of bits of the target RF signal is less than a count of bits of the intermediate RF signal.

6. The device of claim 4, wherein the noise shaping unit is further configured to:
perform, based on the noise filter coefficient, noise shaping on the initial RF signal or the intermediate RF signal through a noise shaping filter.

7. The device of claim 6, wherein one or more parameters of the noise shaping filter correspond to the resonance frequency of the excited nuclide.

8. The device of claim 6, wherein the pulse generation module includes two or more noise shaping units, and one or more parameters of at least one of two or more noise shaping filters corresponding to the two or more noise shaping units are different from parameters of other noise shaping filters.

9. The device of claim 6, wherein the noise shaping includes:
obtaining a signal to be optimized;
obtaining, based on the signal to be optimized, a disturbance signal, the disturbance signal being a preset count of low bits in the signal to be optimized;
inputting the disturbance signal into the noise shaping filter, the noise shaping filter outputting a disturbance optimization signal;
obtaining, based on the initial RF signal or the intermediate RF signal, and the disturbance optimization signal, an optimized signal; and
obtaining, based on the optimized signal, the target RF signal.

10. The device of claim 4, wherein the pulse generation module includes at least one pulse generation channel, each of the at least one pulse generation channel corresponds to one noise shaping unit, and the one noise shaping unit is configured to receive the noise filter coefficient corresponding to the at least one pulse generation channel, and perform, based on the noise filter coefficient, noise shaping on the initial RF signal or the intermediate RF signal corresponding to the pulse generation channel.

11. The device of claim 10, wherein the pulse generation module further includes at least one digital-to-analog conversion unit corresponding to the at least one pulse generation channel, the at least one digital-to-analog conversion unit is configured to perform digital-to-analog conversion on the target RF signal of the at least one pulse generation channel corresponding to the least one digital-to-analog conversion unit.

12. The device of claim 10, wherein the pulse generation module further includes:
at least one merging unit corresponding to two or more of the at least one pulse generation channel and configured to merge the target RF signals output by the two or more of the at least one pulse generation channel to output a merged target RF signal; and
at least one digital-to-analog conversion unit connected with the at least one merging unit and configured to perform digital-to-analog conversion on the merged target RF signal.

13. The device of claim 4, wherein
the pulse generation module includes multiple pulse generation channels and at least one merging unit;
the at least one merging unit correspond to two or more of the multiple pulse generation channels and configured to merge the initial RF signals output by the two or more of the at least one pulse generation channels to output an intermediate RF signal; and
the at least one noise shaping unit is connected with the at least one merging unit and configured to receive the noise filter coefficient corresponding to the at least one pulse generation channel, and perform, based on the noise filter coefficient, noise shaping on the intermediate RF signal output by the at least one merging unit to output the target RF signal.

14. (canceled)

15. The device of claim 10, wherein the pulse generation channel includes a frequency mixing link, and the frequency mixing link is configured to receive the baseband signal and the frequency tuning word corresponding to the at least one pulse generation channel, and generate, based on the baseband signal and the frequency tuning word, the initial RF signal.

16. The device of claim 15, wherein the frequency mixing link includes:
a numerically controlled oscillator configured to generate, based on the frequency tuning word, a local oscillation signal; and
an up-conversion modulator connected with the numerically controlled oscillator and configured to generate, based on the local oscillator signal and the baseband signal, the initial RF signal.

17. The device of claim 4, wherein the pulse generation module further includes a switch connected with the noise shaping unit and configured to build or block a connection between the noise shaping unit and the at least one pulse generation channel.

18. The device of claim 1, wherein the coefficient generation module is further configured to:
determine, based on the frequency tuning word and one or more system configuration parameters of a magnetic resonance device, the noise filter coefficient.

19-21. (canceled)

22. The device of claim 1, further comprising:
an emission link, configured to perform signal conditioning and power amplification on the target RF signal; and
an emission coil connected with the emission link and configured to transmit, based on a signal output by the emission link, an imaging RF signal.

23. A method for improving a dynamic range of a magnetic resonance radio frequency (RF) emission signal, comprising:
inputting a magnetic resonance sequence instruction, and outputting a baseband signal and a frequency tuning word corresponding to a preset frequency;
outputting, based on the frequency tuning word, a noise filter coefficient; and
outputting a target RF signal based on the baseband signal, the frequency tuning word, and the noise filter coefficient.

24. A magnetic resonance imaging (MRI) system, comprising an imaging device and a radio frequency (RF) emission unit, wherein the RF emission unit is connected with the imaging device, and the RF emission unit includes a host computer and a device for improving a dynamic range of a magnetic resonance RF emission signal, wherein
the host computer is configured to send a magnetic resonance sequence instruction; and
the device includes:
an instruction processing module, configured to receive the magnetic resonance sequence instruction and output a baseband signal and a frequency tuning word corresponding to a preset frequency;
a coefficient generation module, configured to output, based on the frequency tuning word, a noise filter coefficient; and
a pulse generation module, configured to output a target RF signal based on the baseband signal, the frequency tuning word, and the noise filter coefficient.
